(19) United States
(12) Patent Application Publication
(10) Pub. No.: US 2023/0393209 A1
(43) Pub. Date: Dec. 7, 2023

(54) PACK LEVEL STATE-OF-POWER PREDICTION FOR HETEROGENEOUS CELLS

(71) Applicants: TotalEnergies OneTech SAS, Courbevoie (FR); The Regents of the University of California, Oakland, CA (US); Universite Libre De Bruxelles, Bruxelles (BE)

(72) Inventors: Chitra DANGWAL, Berkeley, CA (US); Scott MOURA, Berkeley, CA (US); Preet GILL, El Sobrante, CA (US); Dong ZHANG, Albany, CA (US); Luis COUTO, Oxford (GB); Wente ZENG, San Francisco, CA (US); Sebastien BENJAMIN, Leognan (FR)

(73) Assignees: TotalEnergies OneTech SAS, Courbevoie (FR); The Regents of the University of California, Oakland, CA (US); Universite Libre De Bruxelles, Bruxelles (BE)

(21) Appl. No.: 17/832,291

(22) Filed: Jun. 3, 2022

(51) Int. Cl. G01R 31/3842; H02J 7/00; G01R 31/396; G01R 31/374; G01R 31/367

(52) U.S. Cl. CPC G01R 31/3842; H02J 7/0048; G01R 31/396; G01R 31/374; G01R 31/367

(57) ABSTRACT

A method of predicting state of power (SOP) for a battery includes estimating first state parameter bounds of the battery using an internal observer process; obtaining a current value based upon the first state parameter bounds, system constraint variables, a scaling factor and a reference current using a modified reference governor process; performing adaptive parameter bounding to obtain second state parameter bounds using the current value; determining a constraint variable based upon the second state parameter bounds and whether the constraint variable is within the system constraint variables the using an interval prediction process; and generating a modified scaling factor based upon whether the constraint variable is within the system constraint variables. Using the modified scaling factor, the obtaining, performing, determining and modifying are repeated to generate a final current value. The SOP is estimated based upon the final current value.

### BACKGROUND OF THE INVENTION

### Field of the Invention

The present application is directed to power prediction for a battery pack with heterogeneous cells.

### Discussion of the Background

With increasing electrification in every domain of technology, the importance of energy storage systems is immense. Lithium-ion batteries have played a key role and have become ubiquitous in many applications, especially the automotive industry and grid energy storage. These batteries are being constantly improved to extract their maximum potential, which means pushing the operational limits, safely. Accurate estimation of the battery's state hence becomes critical to increasing performance.

To quantify cell performance, different ‘states of performance’ are defined. For example, state of charge (SOC) is an indication of the available battery capacity at any instant. State of health (SOH) is an indication of battery age and degradation. SOP similarly provides information about the peak power performance of the cell. Power performance of an electrified vehicle is translated to the acceleration, braking, charging, or climbing capacity of the vehicle, which is directly related to the discharge and charging capability of the vehicle's battery. Unlike SOC and SOH, where myriad research publications have been produced, the available literature on SOP estimation remains limited, despite its critical role for providing safe charge/discharge limits.

The two main methods for SOP estimation can be categorized as: (i) the characteristic map based method, and (ii) the model-based prediction method. See Lu J, Chen Z, Yang Y, Ming L V. Online estimation of state of power for lithium-ion batteries in electric vehicles using genetic algorithm. IEEE Access. 2018 Apr. 16; 6:20868-80, the contents of which are herein incorporated by reference. The former is a straightforward method that uses maps of power parameters and battery states stored offline in the BMS (Lu, supra, and Farmann A, Sauer D U. A comprehensive review of on-board State-of-Available-Power prediction techniques for lithium-ion batteries in electric vehicles. Journal of Power Sources, 2016 Oct. 15; 329:123-37, the contents of which are herein incorporated by reference). Although this technique is very easy to implement, the accuracy is limited for a number of reasons. Firstly, the maps are designed from the battery's static characteristics, and ignore the dynamic behavior. Secondly, the method is open loop and not closed-loop. This makes it susceptible to modeling and measurement errors Lu and Farmann, supra. The model-based SOP estimation method, on the other hand, is more accurate and robust since it accounts for dynamics and utilizes feedback. The second method uses a battery model to describe the cell dynamics. The most common model used is the equivalent circuit model (ECM) Lu and Farmann, supra. Commonly, Taylor series expansion is used to approximate the nonlinear voltage output function, and the battery is subject to constraints on current, voltage and SOC. Lu, supra; Plett G L. High-performance battery-pack power estimation using a dynamic cell model. IEEE Transactions on vehicular technology. 2004 Sep. 27; 53(5):1586-93, and Farmann, supra, the contents of which are herein incorporated by reference. This method is also vulnerable to inaccuracies, due to errors associated with Taylor series approximation and the omission of time-varying (state-dependent) parameters.

Lu, supra, presents an SOP estimation method using a genetic algorithm as an improvement over Taylor's method, to increase accuracy at longer time-scales. Xavier M A, de Souza A K, Trimboli M S. An LPV-MPC Inspired Battery SOP Estimation Algorithm Using a Coupled Electro-Thermal Model, In 2021 American Control Conference (ACC) 2021 May 25 (pp. 4421-4426), IEEE, the contents of which are herein incorporated by reference, includes thermal dynamics in the ECM model and introduces a linear parameter-varying (LPV) model predictive control (MPC) based method for SOP. The LPV model accounts for parameter variations in the ECM, and MPC is used for accurate power estimation. Finally, the articles Liu X, He Y, Zeng G, Zhang J, Zheng X. State-of-Power Estimation of Li-Ion Batteries Considering the Battery Surface Temperature, Energy Technology. 2018 July; 6(7):1352-60; Jin Z, Zhang Z, Aliyev T, Rick A, Sisk B., Estimating the power limit of a Lithium battery pack by considering cell variability, SAE Technical Paper; 2015 Apr. 14, the contents of both of which are herein incorporated by reference; and Xavier, supra, include temperature constraints (in addition to SOC, voltage and power limits) to define a safe area of battery operation. Most of the existing SOP estimation techniques focus on a single cell. Only a few address the challenges associated with estimating power in a pack.

A battery pack consists of many cells arranged in a series-parallel fashion to reach a desired voltage and capacity. The cells have inherent heterogeneity that arises from micrometer length scale effects (electrode particle densities, porosity, radius etc.) to macro length scale effects (cell manufacturing and assembly, external temperature variation). When modeling packs, a nominal set of parameters is considered to represent all cells Lu and Plett, supra. This assumption is valid if parameter heterogeneity is negligible, or at relatively low currents with low cell-to-cell temperature variation. For power prediction, where the objective is to evaluate the maximum current of the battery, heterogeneity among the cells significantly impacts overall pack power. Hence, heterogeneity needs to be accounted. See, Jiang B, Dai H, Wei X, Zhu L, Sun Z. Online reliable peak charge/discharge power estimation of series-connected lithium-ion battery packs, Energies, 2017 March; 10(3):390; Zhou Z, Kang Y, Shang Y, Cui N, Zhang C, Duan B., Peak power prediction for series-connected LiNCM battery pack based on representative cells, Journal of Cleaner Production, 2019 Sep. 1; 230:1061-73; and Waag W, Fleischer C, Sauer D U. Adaptive on-line prediction of the available power of lithium-ion batteries, Journal of Power Sources, 2013 Nov. 15; 242:548-59; the contents of each of which are herein incorporated by reference.

Cell heterogeneity can cause differences in the peak power availability among cells. The few existing techniques to address heterogeneity are based on two approaches. The first approach is to monitor the state of all the cells in a pack Jiang, supra. The second approach is to identify the ‘weakest’ cells in a pack Zhou and Wang, supra. The former approach, where all the cells are monitored, results in accurate power prediction but requires substantial computational power and memory for processing and storing data on each cell Zhou and Wang, supra. These problems escalate significantly with the number of cells in the pack. The latter method relies on identifying the ‘weakest’ cells for power prediction, and then applies single cell techniques. This usually relies on certain assumptions about the cell characteristics, e.g. some parameters are homogeneous and/or follow prescribed patterns Zhou and Wang, supra. This method uses less computation and memory than the first method, but is not as accurate because the assumptions about cell characteristics generally do not hold true. Also, the set of possible weakest cells increases substantially with the number of cells in a pack.

### SUMMARY OF THE INVENTION

The present invention is direct to a method and system where the heterogeneity of the cells in the pack is considered using the concept of interval prediction. Interval prediction deals with estimation of bounds of states of the system, hence focusing just on upper and lower boundaries of a system rather than any individual state. The battery cell model is considered as an uncertain parametric system. A reachability analysis approach is used for state interval prediction. Considering all these factors into account, for the uncertain parameter varying ECMT (equivalent circuit model including thermodynamics) system under study, the reachability problem is addressed by using the property of mixed monotonicity.

Reachable set calculation tests the robustness of the ECMT system against parameter uncertainty and checks that the system does not reach any unsafe state. The battery model consists of an uncertain ECM parameter and uncertainty in the thermal model.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a diagram of an equivalent cell model for a battery cell;

FIG. 2 is a diagram of a battery cell configuration model with m heterogeneous cells;

FIG. 3 is a diagram of cell voltage responses for 50 heterogeneous cells connected in series under HPPC cycle;

FIG. 4 is a graph illustrating the diagnostic current profile used in HPPC cycle of FIG. 3;

FIGS. 5A-5C illustrate parameter variations in battery cells over SOC and temperature;

FIG. 6 is a block diagram of a first embodiment of the method according to the invention;

FIG. 7 illustrates a Modified Reference Governor;

FIG. 8 is a graph of an input current profile;

FIGS. 9A-9C show state and output profiles for battery cells;

FIGS. 10A and 10B are graphs illustrating SOP prediction for charg13ing and discharging, respectively;

FIG. 11 is a diagram of the second embodiment according to the invention;

FIGS. 12A-12D are graphs illustrating state interval prediction for constant charging current;

FIGS. 13A-13D are graphs illustrating state interval prediction for constant discharging current;

FIG. 14 is a graph illustrating the current profile for Case 1;

FIGS. 15A-15C show the evolution of the voltage response and the state dynamics of the cells subject to the current profile of FIG. 14;

FIGS. 16A-16B are graphs illustrating SOP prediction for charging and discharging, respectively;

FIG. 17 is a graph illustrating household load and solar PV generation;

FIG. 18 is a graph illustrating the current profile for Case 2;

FIGS. 19A-19C are graphs illustrating the state and output profiles for the modules in Case 2;

FIGS. 20A-20B are charts illustrating SOP charging and discharging current prediction for Case 2;

FIG. 21 is a diagram of a first embodiment of the system according to the invention;

FIG. 22 is a diagram of a second embodiment of the system according to the invention; and

FIG. 23 is a diagram of a third embodiment of the system according to the invention.

### DESCRIPTION OF THE PREFERRED EMBODIMENTS

Battery Modelling

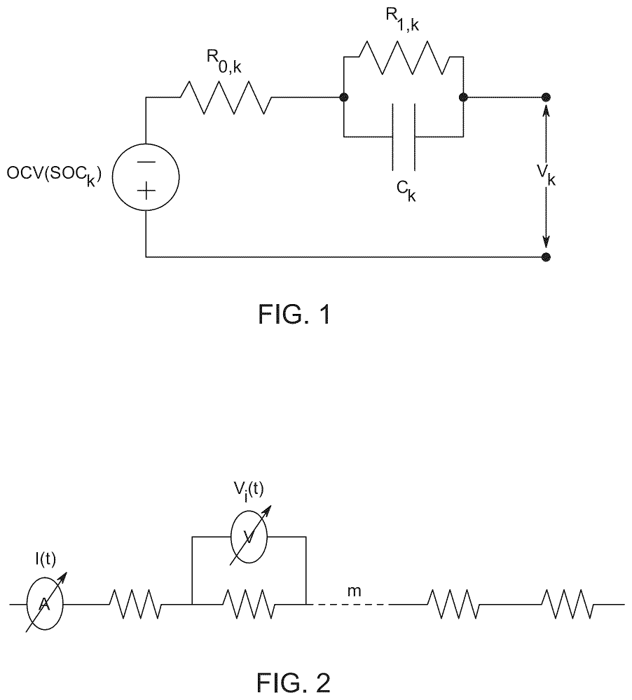

The cell dynamics of a battery are modeled by an ECM coupled with two state thermal models. Even though physics-based models have the advantage of accurately representing the system over heuristic-based models, the advantage the data driven heuristic models offers in terms of modeling simplicity, computation effort, make it ideally suited for control-oriented applications. The ECM of a battery cell is shown in FIG. 1. The cell includes R₀ representing an equivalent ohmic internal resistance and the resistor-capacitor parallel network where R₁ is the equivalent polarization resistance and C is the equivalent polarization capacitance. The configuration of the battery pack is considered a set of heterogeneous cells (or modules) connected in series as seen in FIG. 2. The OCV of the cell is denoted by Voc(z) and the losses in the cells are modelled by using the ohmic resistance R₁ and the RC pair. FIG. 1 shows the voltage response Vₖ of and individual cell ‘k’.

Electrical Part

The voltage dynamics of a single cell k, using ECM can be represented as follows:

$${t}_{k} ( t ) = \frac{1}{{Q}_{k}} {I}_{k} ( t ) , \qquad ( 1 )$$

$${\dot{V}}_{c , k} = - \frac{1}{{R}_{1 , k} ( {z}_{k} , {T}_{k} ) {C}_{k} ( {z}_{k} , {T}_{k} )} {V}_{c , k} + \frac{1}{{C}_{k} ( {z}_{k} , {T}_{k} )} {I}_{k} ( t ) , \qquad ( 2 )$$

$${V}_{k} ( t ) = OCV ( {z}_{k} ( t ) ) - {V}_{c , k} ( t ) - {R}_{0 , k} ( {z}_{k} , {T}_{k} ) {I}_{k} ( t ) , \qquad ( 3 )$$

Where state of charge (SOC) and capacitance voltage V_{c} represent the state of the system, and the overall cell voltage Vₖ is the output of the system. Iₖ(t) is the current flowing in the model. The parameters of the electrical part of the model are Qₖ, R_{0,k}, R_{1,k} and Cₖ. It should be noted that the while the cell capacity Qₖ is heterogeneous in the pack, the parameters R_{0,k}, R_{0,k} and Cₖ are heterogeneous as well as temperature dependent.

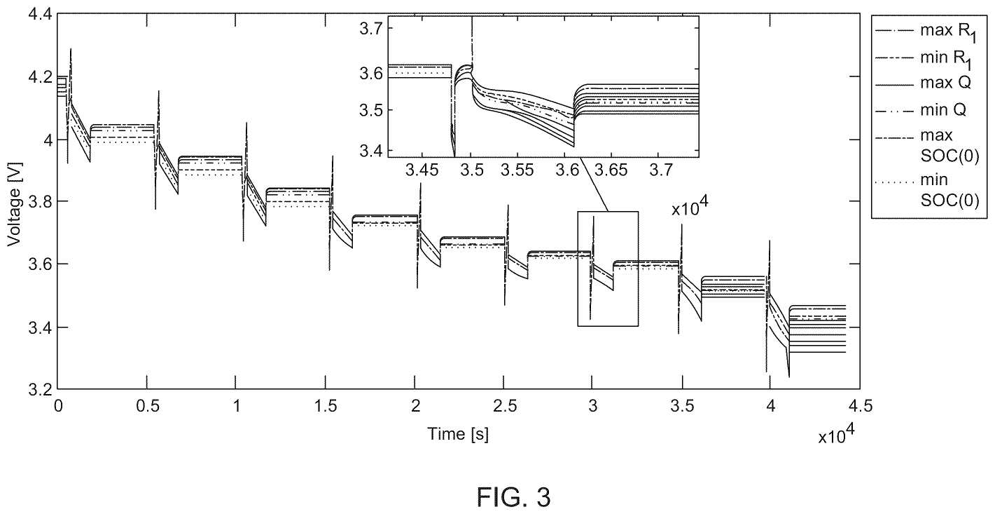

The voltage response of the ECM is shown in FIG. 3 to a modified Hybrid Pulse Power Characterization (HPPC) test cycle at a temperature of 30° C. to a battery pack with 50 cells in series. The HPPC cycle was used to determine the dynamic performance characteristics of a battery. This testing determines battery power capability over the usable voltage range of the cell. The test profile incorporates a discharge pulse followed by a regeneration pulse that take place at various states of charge (SOC), and which can be performed under various temperature stressors and current loads. A discharge pulse is a relatively short load drawn on the battery, and a regeneration pulse is a relatively short charge to the battery. In the test cycle of FIG. 3, the discharge/regeneration pulses are repeated every 0.5×10⁴ seconds and voltage curves for each of the cells are obtained as a function of input current. This profile mimics the discharge and charge that can occur on hybrid EVs during acceleration and regenerative braking. In the HPPC cycle, all three types of the aforementioned heterogeneity are applied to the pack of 50 cells, simultaneously, where the parameters and SOC are within ±5% of the fresh cell electrical parameters at 30° C., as shown in FIG. 3.

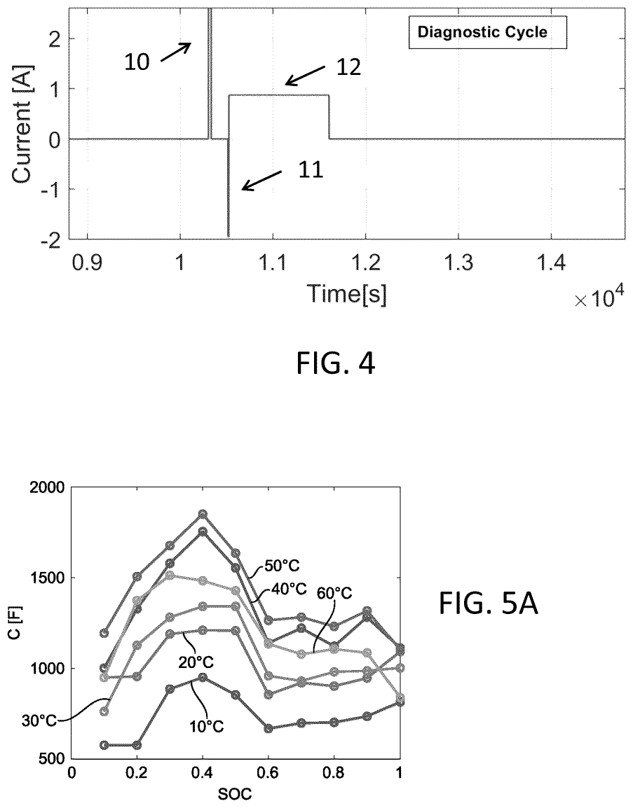

FIG. 4 shows diagnostic pulse current profile used in the diagnostic cycle. The pulse current profile provides a discharge pulse 10 (positive current) followed by a charge (regenerative) pulse which includes a negative current portion 11 and positive current portion 12. The values of the pulses are chosen based upon the battery characteristics and testing considerations. Other voltage and timing values than those shown may be used.

Thermal Part

The temperature dynamics is modelled by considering two thermal states for each cell, i.e., core temperature T_{c,k} and surface temperature T_{s,k}. Thermally the cell is modelled as two-point masses representing core and surface of the cell, of capacitance C_{c,k} and C_{s,k} respectively. The energy losses in the cell which causes deviation of cell output voltage from its OCV, results in heat dissipation q̅ₖ, which results in rise of cell temperature (Equation (4)). The cell is being cooled by a coolant at temperature T_{f}. The heat exchange between core and surface and then surface and coolant is modeled using thermal resistances R_{C,k} and R_{u,k} respectively. The resistance Re accounts for heat exchange between neighboring cells as seen in equation (5).

The thermal dynamics of the cell is given by the following equations:

$${C}_{c} {\dot{T}}_{c , k} ( t ) = {\dot{q}}_{k} ( t ) + \frac{{T}_{s , k} ( t ) - {T}_{c , k} ( t )}{{R}_{c}} , \qquad ( 4 )$$

$${C}_{s} {\dot{T}}_{s , k} ( t ) = \frac{{T}_{f , k} ( t ) - {T}_{s , k} ( t )}{{R}_{u}} - \frac{{T}_{s , k} ( t ) - {T}_{c , k} ( t )}{{R}_{c}} , \qquad ( 5 )$$

$${\dot{q}}_{k} ( t ) = {I}_{k} ( t ) ( {V}_{k} ( t ) - OCV ( {z}_{k} ( t ) ) , \qquad ( 6 )$$

$${T}_{k} ( t ) = \frac{1}{2} ( {T}_{s , k} ( t ) + {T}_{c , k} ( t ) ) . \qquad ( 7 )$$

SOP Definition

Unlike SOC and SOH, which have a definite mathematical meaning, SOP definition is not concrete. The common description of SOP is the prediction of peak power that a battery can constantly sustain for a given (finite) time horizon without subjecting the battery/cell to any unsafe operating condition. Since battery loads in many applications are often difficult to predict, the reference case of constant current, constant voltage is used to define SOP. The safe operating regime of the cell is guided by the safety limit of the cell defined by variables like voltage, temperature, etc. These safety limits ensure that the cells are not subjected to conditions that are detrimental to the health of the battery (e.g., overcharge, over discharge, extreme temperatures etc.) and avoid any instantaneous battery failures like thermal runaway. Also, the power capacity of the battery can be difficult to predict without any prior information about the load/cycle under which the battery will undergo.

In the present invention, SOP is defined as peak power prediction. Typically for SOP prediction, the constant peak power prediction is further simplified to constant peak current prediction, as voltage remains almost constant during majority of a constant current cycle, over a fixed prediction time horizon Tₚ without violating the safely constraints.

The safety limits considered in the present invention for the prediction of SOP are voltage, SOC, temperature and maximum current. An example for a NMC-graphite cell with 2.6 Ah nominal capacity is given in Table 1:

TABLE 1
Safety Constraint Parameters

| | | |
|---|---|---|
| Constraints | Lower Limit | Upper Limit |

| | | | | |
|---|---|---|---|---|
| Voltage: Vₘᵢₙ ≤ V ≤ Vₘₐₓ | 2.8 | V | 4.2 | V |

| | | |
|---|---|---|
| SOC: SOCₘᵢₙ ≤ SOC ≤ SOCₘₐₓ | 0.1 | 1 |

| | | | | |
|---|---|---|---|---|
| Current: Iₘᵢₙ ≤ I ≤ Iₘₐₓ | −10 | C | 10 | C |
| Temperature: Tₘᵢₙ ≤ T ≤ Tₘₐₓ | 10° | C. | 60° | C. |

It should be noted that the values chosen as safety constraints in Table 1 are set based on a general sense of cell safety. These values can be changed based on individual application safety requirements. Also the invention is applicable to any cell chemistry and the corresponding specific safety constraints.

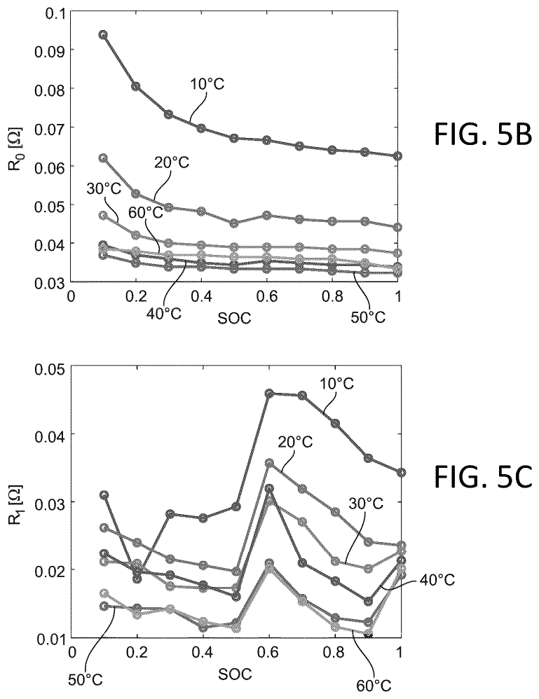

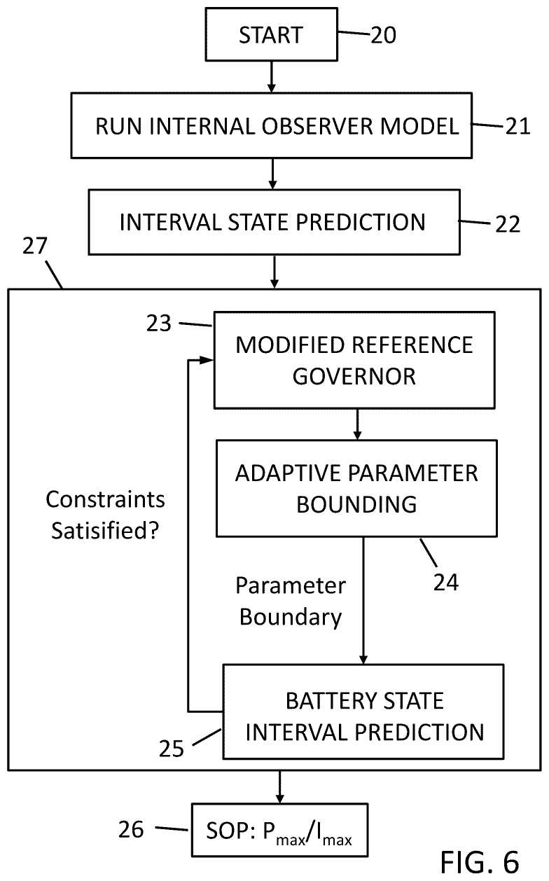

The two main challenges of SOP prediction when considering the battery pack are parametric heterogeneity and state dependence. The system and method according to the invention have parametric uncertainty. The parametric uncertainty considered is both in electrical and thermal parameters. The electrical parameters (R₀, R₁, C) are not only uncertain but are also state dependent (i.e., functions of SOC and temperature). FIGS. 5A-5C show typical variations with states (both SOC and temperature) of ECM parameters for a 2.6 Ah NMC cell.

Scaling the power estimation problem from the cell level to the pack level increases complexity. Due to cell-to-cell interactions, the dynamics of a single cell are affected by the neighboring cells. Moreover, the inherent cell-to-cell heterogeneity means one cannot simply use a single representative cell for the entire pack.

In the HPPC cycle of FIG. 3, parameters for each cell are chosen at random from a uniform distribution, whose mean is the nominal value of the parametric set. In the simulation, ±50% parametric variation is considered in the ECM parameters i.e. R₀, R₁, C; ±5% variation is considered in the cell capacity Q; and ±5% variation is considered in initial SOC, z(0). Note that none of the cells with extreme parameters in terms of capacity, ohmic resistance or initial SOC can be deemed as the uniformly “limiting/extreme” cells of the pack. In fact, the limiting cells are sometimes from the interior of the parametric distribution, and can change throughout the cycle. FIG. 3 shows that the limiting cell is not always the cell with least capacity or highest ohmic resistance. It could be any cell whose combination of parameters makes it the most extreme. As the parameters are state dependent, different cells could be the limiting cell at different points of time.

In a first embodiment, the system and method comprises a parameter varying system (PVS) with uncertain parameters. The parameters R₀, R₁, C are state (SOC and temperature) dependent. The parameter Q is uncertain as well. Temperature differences between the cells are also introduced because of different heat generation among the cells. The SOP prediction can be stated as determining discharge current and power I_{max,pack}^{dis} and P_{max,pack}^{dis} for discharge limits and determining charging current and power I_{max,pack}^{ch} and P_{max,pack}^{ch} for charge limits.

For a chosen prediction time horizon Tₚ, the maximum constant current that can be supplied to the battery pack with m cells at any instant t is:

I_{max,pack}^{dis}=min_{k=1, . . . m}(I_{max,k}^{dis})

I_{max,pack}^{ch}=min_{k=1, . . . m}(I_{max,k}^{ch}) (8)

where I_{max,pack}^{dis} and I_{max,pack}^{ch} are the maximum constant discharge and charge current applicable for the entire battery pack, and I_{max,k}^{dis} and I_{max,k}^{ch} are the maximum current applicable to the cell k of the pack.

The maximum constant current of each cell k further is calculated by considering the SOC, voltage, temperature and current constraints of each cell.

I_{max,k}^{dis}=min(i_{max,k}^{dis|SOC},i_{max,k}^{dis|V},i_{max,k}^{dis|T},i_{max,k}^{dis|I})

I_{max,k}^{ch}=min(i_{max,k}^{ch|SOC},i_{max,k}^{ch|V},i_{max,k}^{ch|T},i_{max,k}^{ch|I}) (9)

where:

i_{max,k}^{dis|SOC}, i_{max,k}^{dis|V}, i_{max,k}^{dis|T}, i_{max,k}^{dis|I} are the maximum constant current discharge pulse that can be applied for Tp duration, without violating the SOC, voltage, temperature and current constrains, respectively, for any cells in the pack, and

i_{max,k}^{dis|SOC}, i_{max,k}^{dis|V}, i_{max,k}^{dis|T}, i_{max,k}^{dis|I} are the maximum constant current charge pulses that can be applied for Tp duration, without violating the SOC, voltage, temperature and current constrains, respectively, for any cells in the pack.

SOP can thus be estimated (bounded) for the pack with m cells in series as:

$$SOP : \{ \begin{matrix}{P}^{dis} = m \cdot {I}_{max , pack}^{dis} \cdot \underline{V} ( {I}_{max , pack}^{dis} ) \\ {P}^{ch} = m \cdot {I}_{max , pack}^{ch} \cdot \underline{V} ( {I}_{max , pack}^{ch} )\end{matrix} \qquad ( 10 )$$

$$where :$$

$$\underline{V} ( {I}_{max , t}^{dis} ) = \{ V ( {I}_{max , t}^{dis} ) \vert ∀ \{ 1 , … m \} , t ∈ [ t , t + {T}_{P} ] \} , and$$

$$\underline{V} ( {I}_{max , t}^{c h} ) = \{ V ( {I}_{max , t}^{c h} ) \vert ∀ \{ 1 , … m \} , t ∈ [ t , t + {T}_{P} ] \} .$$

The SOP prediction is designed to find the maximum current such that safe operating conditions are satisfied. To handle cell heterogeneity, bounds are estimated on the state trajectories under parameter uncertainty, rather than evaluating the states of all cells. This is formalized by considering a dynamical system:

\dot{x}=f(t,x,p) (11)

where x represents the states and p represents the parameter, x(t:t₀,x₀, p) indicates the state of the system at time t≥t₀ given the initial condition x₀. For the ECMT system formulated as equation (11), the objective is to determine bounds on the state trajectories, given uncertain parameters and the initial conditions. This is accomplished by computing upper and lower bounds on the ECMT state trajectories, i.e.

x(t;t_{0,}x_{0,}p)⊂[x(t),x̅(t)]. (12)

The state bounds for the EMCT are given by:

SOC(t)≤SOCₖ≤S̅O̅C̅(t)

V_{c}(t)≤V_{c,k}≤V̅_̅{̅c̅}̅(t)

T_{c}(t)≤T_{c,k}≤T̅_̅{̅c̅}̅(t)

Tₛ(t)≤T_{s,k}≤T̅ₛ̅(t) (13)

OCV is considered to be a monotonic function of SOC which leads to the following when I(t)≥0:

V̅(t)=OCV(S̅O̅C̅(t))+V̅_̅{̅c̅}̅(t)+I(t)R_{0,max} (14)

V(t)=OCV(SOC(t))+V_{c}(t)+I(t)R_{0,min} (15)

T̅(t)=½(T̅_̅{̅c̅}̅(t)+T̅ₛ̅(t)),T(t)=½(T_{c}(t)+Tₛ(t)) (16)

For SOP prediction during charging, the following constraints are used:

Iₘₐₓ:V̅(t)≤Vₘₐₓ;S̅O̅C̅(t)≤SOCₘₐₓ;T̅(t)≤Tₘₐₓ (17)

Similarly for discharging, the following constraints are used:

Iₘᵢₙ:Vₘᵢₙ≤V(t);SOCₘᵢₙ≤SOC(t);Tₘᵢₙ≤T(t) (18)

FIG. 6 shows a first embodiment of the method according to the invention. The method begins in Step 20 and proceeds to run an internal observer model in Step 21. The internal observer model initializes the state intervals through an estimation process described below. A relaxed approximation of the initial condition can directly lead to over-approximations in the state interval trajectory predictions. Accurate and tight initialization of the state intervals leads to accurate interval prediction. Note that in most cases full knowledge of the vectors of the states is never available. Typically, only voltage, current, and temperature are measured. Consequently, the state must be estimated, via observers, from measured outputs in real-time.

Battery systems have a battery management system (BMS) that can measure the overall series current and the individual cell voltage overtime in the system. Executing state estimation for all cells is intractable, particularly in large systems with many batteries. Heterogeneity between the cells also presents issues. The BMS is capable of providing the maximum and minimum outputs at every time instance. These outputs are used in the internal observer model to generate upper and lower bounds on the uncertain parameters, as described below.

Connected heterogeneous cells are considered and precise state interval initialization for power prediction at any given instant is conducted. A framework of interval observers is preferably used as described in Zhang D, Couto L D, Gill P S, Benjamin S, Zeng W, Moura S J. Thermal-Enhanced Adaptive Interval Estimation in Battery Packs With Heterogeneous Cells, IEEE Transactions on Control Systems Technology, 2021 Jul. 5 (hereinafter Zhangl), the contents of which are incorporated herein by reference, which uses a similar battery-cell configuration. The main idea of the interval observer is similar to interval prediction: estimate the state intervals for an uncertain parameter system, given measurements, i.e. voltage and temperature.

The interval observer in the invention is based on monotone/cooperative system theory, which considers cell heterogeneity and state-dependent parameters as unknown, but bounded uncertainties. The resulting interval observer maps the bounded uncertainties to a feasible set of SOC and temperature estimation for all cells in the pack at each time instant.

The state interval estimates (based on ECMT) of a heterogeneous battery pack x̅(t) and x(t) are obtained using the following assumptions:
1) parametric uncertainty bound is known: θ̅<θ(t)<θ,
2) initial condition bounds are known: x̅₀̅<x₀<x₀, and
3) the maximum/minimum voltage and surface temperature across all series-connected cells are measured, along with current:

y(t)=[I(t),maxVₖ(t),maxT_{s,k}(t),minVₖ(t),m inT_{s,k}(t)] (19)

The voltage, current and temperature measurements can be obtained from the battery management system (BMS) for any cycle the battery undergoes.

The state intervals for the ECMT system are obtained using Lie derivatives, by first converting the nonlinear model dynamics into a partial-linear form:

\dot{ξ}ₖ=A₀ξₖ+δA(θₖ)ξₖ+b(ξₖ,θₖ,u) (20)

Vₖ=Hξₖ+δh(θₖ)u (21)

ξ̅(t) and ξ(t) are the upper and lower bound estimates for a state ξ(t), respectively. The interval observer is based on the lemma in Zhang, supra. The following provides the dynamics to obtain the interval estimates:

\overline{\dot{ξ}}=(A₀−L̅H)ξ̅+(δ̅A̅⁺ξ̅⁺−δ̅A̅⁺ξ̅⁻−δ̅A̅⁻ξ⁺+δ̅A̅⁻ξ⁻)+b̅(t)+L̅y+|L̅|V (22)

\dot{ξ}=(A₀−LH)ξ+(δA⁺ξ⁺−δ̅A̅⁺ξ̅⁻−δ̅A̅⁻ξ̅⁺+δ̅A̅⁻ξ̅⁻)+b(t)+Ly+|L|V (23)

L is the observer gain to be selected. L̅ and L are chosen such that the matrices (A₀−L̅H) and (A₀−LH) are Hurwitz and Metzler. A₀, δA, b, and L are constructed as described in Zhang, supra. For example, the value τₖ=1/(R_{1,k}Cₖ) and a known nominal value τ_{k,0} is selected such that τₖ=τ_{k,0}+δτₖ. For L=[L₁ L₂]^{T}∈ [symbol] ², selecting τ_{k,0}>0, L₂≤0 and L₁>−L₂/τ_{k,0}≥0 then the matrix (A₀−LH) is Hurwitz and Metzler. This leads to choosing τ_{k,0} such that 0<τ_{k,0}≤1/(̅R̅₂C̅) to have δτₖ≥0 for all k∈{1, 2, . . . , m}.

Following the estimates of the intervals, interval state prediction is performed in Step 22. Interval state estimation with observers has been studied for several continuous LPV (linear parameter varying) systems See Efimov D, Raissi T. Design of interval observers for uncertain dynamical systems. Automation and Remote Control. 2016 February; 77(2):191-225; Zhangl, supra; and Zhang, D, Couto, L. D., Gill, P., Benjamin, S., Zeng, W., & Moura, S., J. Interval Observer for SOC Estimation in Parallel-Connected Lithium-ion Batteries, In 2020 American Control Conference (ACC)(pp. 1149-1154). IEEE.; the contents of each of which are herein incorporated by reference, with a fair degree of accuracy, stability and robustness. The availability of output measurement and control over observer gain selection aids in keeping the interval observer state stable and estimation error small. This, however, is not the case when working with state interval prediction. A poorly designed interval prediction algorithm can cause the interval predictor to be unstable, as shown in Leurent, supra, or have very large over-approximation. The interval prediction model used in the invention preferably follows the work in Leurent, supra.

For the given LPV system:

\dot{x}(t)=A(p)x+b(P,u(t)), (24)

where x∈ [symbol] ⁿ is the system state, u(t)∈ [symbol] ^{m} is the input vector andp is the vector of parameters with a known range of uncertainty. Input u(t) is known, and the matrices A∈ [symbol] ^{n×n}, B∈ [symbol] ^{n×m} are both continuous and locally bounded. To design the interval predictor, a system with state vectors [x(t),x̅(t)] is built. The following assumptions are used to construct the state predictor system:
1) the initial uncertainty in the state of the system. i.e., x₀ ∈[x₀, x̅₀̅] is known.
2) the matrix A(p) can be decomposed into a Metzler matrix A₀∈ [symbol] ^{n×n} and matrices ΔAᵢ∈ [symbol] ^{n×n}, i=1, . . . , N where N∈ [symbol] ₊ such that A(p)=A₀+Σᵢ₌₁^{N}λᵢΔAᵢ(p)ΔAᵢ, and
3) a bounding function [b, b̅] exists and is known, such that for all p∈[p, p̅], b≤b(p, u, t)≤b̅.

For a matrix A∈ [symbol] ^{n×n}, A⁺=max{0, A} and A⁻=A⁺−A, and for a vector x∈ [symbol] ⁿ, x⁺=max{0, x} and x⁻=x⁺−x. For the system defined in equation 19 that satisfies the above three assumptions, the state trajectory (equation 19) is enclosed within an interval [x(t),x̅(t)] and the bounds are given as

\dot{x}(t)=A₀x(t)−ΔA₊x⁻(t)−ΔA₋x̅⁺(t)+b (25)

\overline{\dot{x}}(t)=A₀x̅(t)+ΔA₊x̅⁺(t)+ΔA₋x⁻(t)+b̅ (26)

where ΔA₊=Σᵢ₌₁^{N}ΔAᵢ⁺ and ΔA₋=Σᵢ₌₁^{N}ΔAᵢ⁻.

For the ECMT model described above, power prediction is accomplished using the interval predictor design mentioned above. From the model equations, it can be seen that the two states, i.e. (SOC,Vc), that represent the electric part of the model for each cell, are associated with uncertain parameters {R₀, R₁, C, Q}. The thermal parameters of the model, on the other hand, are assumed known, as heterogeneity in thermal properties across the cells is relatively small compared to the heterogeneity in the electric properties. This assumption can be problematic when the thermal parameters vary significantly across the cells.

p=[R_{0,k}R_{1,k}CₖQₖ]∈ [symbol] ⁴ (27)

The heterogeneity as well as state dependence of the above parameters are clubbed together as uncertainty in the model parameters. Bounds on the uncertain parameters are assumed to be known and are given as:

p≤pₖ(t)≤p̅∀k∈{1,2, . . . m}, (28)

where p=[R₀ R₁ C Q], p̅=[R̅₀̅ R̅₁̅ C̅ Q̅]. The ECM model equation can be formulated in the form of (24), where:

$$x = [ \begin{matrix}{x}_{1} \\ {x}_{2}\end{matrix} ] = [ \begin{matrix}SOC \\ {V}_{c}\end{matrix} ] , \qquad ( 29 ‐ 31 )$$

$$A ( p ) = [ \begin{matrix}0 & 0 \\ 0 & - τ\end{matrix} ] , where τ = \frac{1}{{R}_{1} C} ,$$

$$b ( p , u ) = [ \begin{matrix}\frac{1}{Q} \\ \frac{1}{C}\end{matrix} ] I , u ( t ) = I ( t ) .$$

To apply the predictor model equations (25)-(26) to the ECM, the following decomposition of A(p) is applied:

$${A}_{0} = [ \begin{matrix}0 & 0 \\ 0 & - \overline{τ}\end{matrix} ] , Δ {A}_{+} = [ \begin{matrix}0 & 0 \\ 0 & \overline{τ} - \underline{τ}\end{matrix} ] , Δ A … = [ \begin{matrix}0 & 0 \\ 0 & 0\end{matrix} ] \qquad ( 32 )$$

The bounding function for b depends on the sign of current applied. When I≥0

$$\underline{b} = {[ \begin{matrix}\underline{1} & \underline{1} \\ \overline{Q} & \overline{C}\end{matrix} ]}^{T} I , \overline{b} = {[ \begin{matrix}\underline{1} & \underline{1} \\ \underline{Q} & \underline{C}\end{matrix} ]}^{T} I \qquad ( 33 )$$

The resulting state equations during charging (I(t)≥0) hence can be written as:

$$\dot{\underline{SOC}} ( t ) = \begin{matrix}\underline{1} \\ \overline{Q}\end{matrix} I ( t ) , \qquad ( 34 ‐ 37 )$$

$$\dot{\overline{SOC}} ( t ) = \begin{matrix}\underline{1} \\ \underline{Q}\end{matrix} I ( t ) ,$$

$$\underline{{\dot{V}}_{c}} ( t ) = - \overline{τ} \underline{{V}_{c}} - ( \overline{τ} - \underline{τ} ) \overline{{V}_{c}} + \begin{matrix}\underline{1} \\ \overline{C}\end{matrix} I ( t ) ,$$

$${\dot{\overline{V}}}_{c} ( t ) = - \overline{τ} \overline{{V}_{c}} + ( \overline{τ} - \underline{τ} ) \overline{{V}_{c}} + \begin{matrix}\underline{1} \\ \underline{C}\end{matrix} I ( t ) .$$

The thermal part of the model, even with uniform thermal parameters across the cells, still has cell to cell temperature variation caused by non-uniform heat generation. The equations used to predict bounds on the thermal states are:

$$\dot{\underline{ζ}} ( t ) = {A}_{0 , T} \underline{ζ} + Δ {A}_{T} \underline{ζ} + \underline{{B}_{T}} , \qquad ( 38 ‐ 39 )$$

$$\dot{\overline{ζ}} ( t ) = {A}_{0 , T} \overline{ζ} + Δ {A}_{T} \overline{ζ} + \overline{{B}_{T}} ,$$

$$where ζ = [ \begin{matrix}{T}_{c} \\ {T}_{s}\end{matrix} ] and \qquad ( 40 ‐ 42 )$$

$${A}_{0 , T} = [ \begin{matrix}- \frac{1}{{R}_{c} {C}_{c}} & \frac{1}{{R}_{c} {C}_{c}} \\ \frac{1}{{R}_{c} {C}_{s}} & - ( \frac{1}{{R}_{c} {C}_{s}} + \frac{1}{{R}_{c} {C}_{s}} )\end{matrix} ] , Δ {A}_{T} = 0 ,$$

$${B}_{T} = {[ \begin{matrix}\frac{{\dot{Q}}_{k}}{{C}_{c}} & \frac{1}{{R}_{u} {C}_{s}} {T}_{f}\end{matrix} ]}^{T} = {[ \begin{matrix}\frac{{I}_{k} ( {V}_{c} + {IR}_{0} )}{{C}_{c}} & \frac{1}{{R}_{u} {C}_{s}}\end{matrix} {T}_{f} ]}^{T} ,$$

$$\underline{{B}_{T}} = {[ \begin{matrix}\frac{{I}_{k} ( \underline{{V}_{c}} + I {\underline{R}}_{0}}{{C}_{c}} & \frac{1}{{R}_{u} {C}_{s}} {T}_{f}\end{matrix} ]}^{T} , \overline{{B}_{T}} = {[ \begin{matrix}\frac{{I}_{k} ( \overline{{V}_{c}} + I \overline{{R}_{0}} )}{{C}_{c}} & \frac{1}{{R}_{u} {C}_{s}} {T}_{f}\end{matrix} ]}^{T} ,$$

Equations (34)-(39) can be used for state interval prediction. The above analysis accurately predict bounds on the state of the uncertain LPV (ECMT) system, For a given current magnitude, the next step is to determine the maximum current which satisfies the safety constraints.

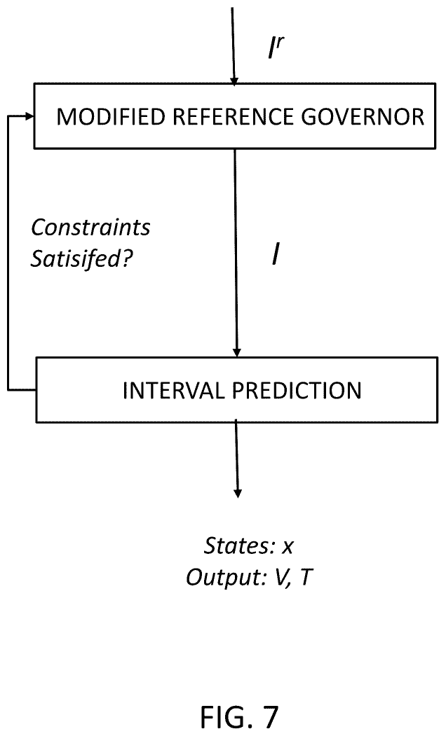

The maximum current is preferably determined using a Modified Reference Governor (MRG) which attenuates an input signal of a dynamical system with a pole at the origin, such that a set of constraints are satisfied (Step 23). The MRG is illustrated in FIG. 7. The MRG is designed to iteratively compute, at any given time instant, the safe applicable current I(t), as close as possible to the reference input current I^{r}(t), such that the system constraints are always satisfied during the SOP prediction time horizon. See Perez H., Shahmohammadhamedani N., Moura S., Enhanced performance of Li-ion batteries via modified reference governors and electrochemical models, IEEE/ASME Transactions on Mechatronics, 2015 Jan. 8; 20(4):1511-20, the contents of which are herein incorporated by reference. This is similar to the bisection approach implemented in Plett, supra, for maximum current computation. The reference current, I^{r}, is generally taken as the maximum safe current. The safe applicable current I(t) is related to I^{r} as follows:

I(t)=αI^{r}(t)∀t∈[t,t+Tₚ]. (43)

Reference current I^{r} is typically a constant value, and α∈[0,1] is the scaling factor that is evaluated to determine I(t). Y represents the set of admissible state/outputs of the system, i.e. SOC ∈[SOCₘᵢₙ, SOCₘₐₓ], V∈[Vₘᵢₙ, Vₘₐₓ] and T∈[Tₘᵢₙ, Tₘₐₓ], and y is determined by the battery interval state predictor 25 i.e. [SOC, S̅O̅C̅, V, V̅, T, T̅], based upon the current from MRG 23. The scaling factor ak is evaluated such that:

α=max{α∈[0,1]:y∈Y,t∈[t,t+Tₚ]. (44)

The maximum value of α∈[0, 1] is obtained which satisfies the safety constraints during the prediction time horizon. This is accomplished by simulating the interval predictor battery model forward in time [t, t+Tₚ] and checking if the constraints are satisfied. MRG initializes with α=1, and finds the optimal α using the bisection algorithm. Battery interval prediction in Step 25 determines bounds of states and output trajectories, based upon the input current I and checks if the constraints are satisfied. If, for a given value of a, the constraints are not satisfied, then the value of a is scaled down (a and a new upper boundary are set to (upper boundary+lower boundary)/2) and the predictor model is re-simulated. On the other hand, if the constraints are satisfied, a is scaled up so as to find the maximum value of a that satisfies the constraints (α and a new lower boundary are set to ((upper boundary+lower boundary)/2). This is shown in FIG. 7 by the “Constraints Satisfied?” feedback loop output from Step 25 where whether the constraints are satisfied causes the MRG to modify α and calculate I again. The process continues until the difference between successive calculations is minimal and the optimal α is thus obtained. The MRG and interval predictor combined provide the SOP algorithm for the battery pack.

The SOP Prediction unit 27 in the invention uses the MRG modified as shown in FIG. 7 to include an Adaptive Parameter Bounding (Step 24). The adaptive parameter bounding is an improvement added to SOP prediction for increasing state prediction accuracy. The battery interval prediction 25 uses the parameter bound [θ̅, θ] for state bound prediction. As mentioned before, the parameters R₀, R₁, C are not constant but are dependent on states (SOC, temperature). Hence, defining ECM parameter bounds are not straightforward. One approach would be to take the extreme values from the ECM parameter maps, but this results in conservative bounds. The adaptive parameter bounding eliminates conservatism by defining a tighter parameter bound based on a localized region of the parameter space. This is done without simulating the model, as follows:
1. For a constant current magnitude, given initial state intervals [SOC₀,T₀] and prediction horizon, the SOC range where SOP prediction is relevant is estimated.

For charging, I>0:

$${SOC}_{high} = \overline{{SOC}_{0}} + {\int }_{0}^{{T}_{p}} \begin{matrix}\underline{I} \\ \underline{Q}\end{matrix} dt ; {SOC}_{low} = \underline{{SOC}_{0}} \qquad ( 45 )$$

For discharging I<0:

$${SOC}_{high} = \overline{{SOC}_{0}} ; {SOC}_{low} = \underline{{SOC}_{0}} + {\int }_{0}^{{T}_{p}} \frac{I}{\underline{Q}} dt \qquad ( 46 )$$

2. Since the ECMT only accounts for irreversible heat generation, both charging and discharging are exothermic. Hence the temperature range where SOP prediction is relevant can be between T₀ and the maximum temperature.

T_{low}=min(T_{f},T₀);T_{high}=Tₘₐₓ

Therefore, the parameter bound [θ̅, θ] determined using the adaptive parameter bounding is taken as the extreme values of the parameter from the SOC and the pertinent temperature region [SOC_{low}, SOC_{high}]×[T_{low}, T_{high}]. Thus,

[θ̅(t),θ(t)]=θ_{max.min}(SOC:S̅O̅C̅,T:T̅)

This is shown in FIG. 6 as parameter mapping which is used in the battery state interval prediction of Step 25.

The SOP is determined in Step 26 using the current from Steps 23-25 as Iₘₐₓ. As mentioned above SOP translates to Iₘₐₓ since the voltage is relatively constant over the cycle. Pₘₐₓ is determined from Iₘₐₓ and the cycle voltage.

### Example

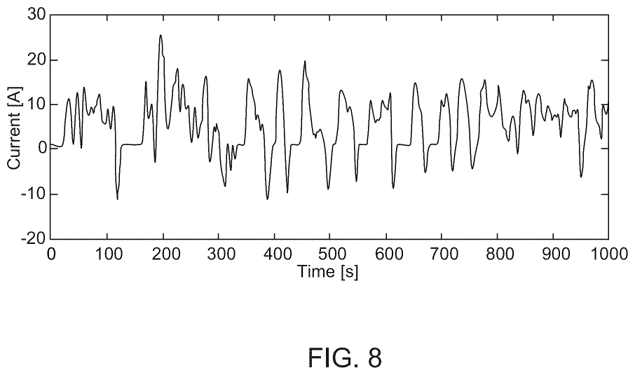

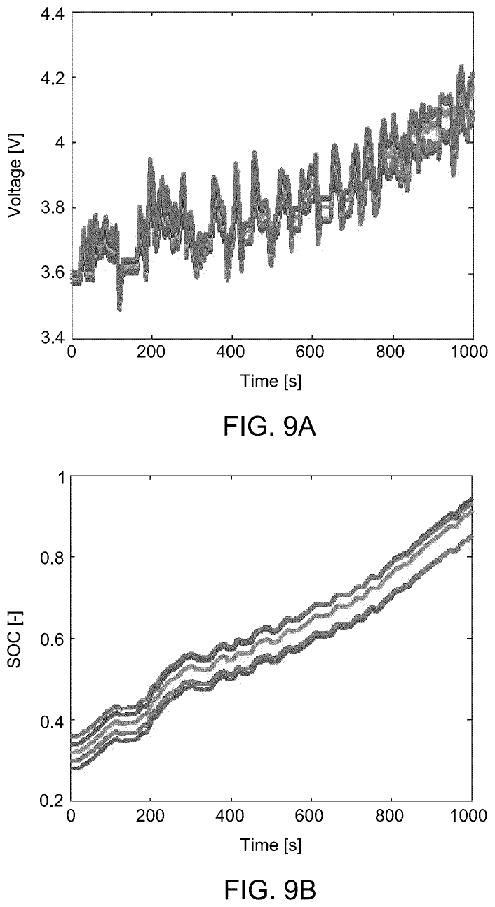

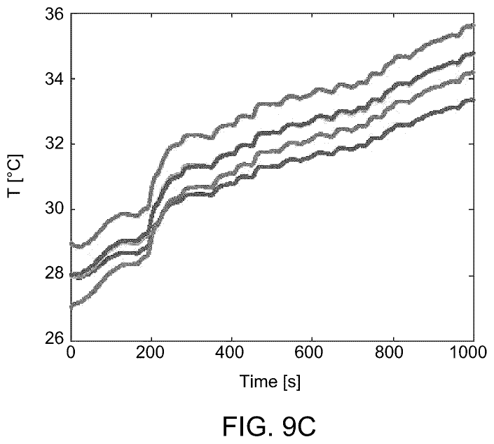

The SOP algorithm according to the invention developed for heterogeneous cells in series was tested, via simulation. An NMC cell with 2.6 Ah nominal capacity is used. The cell data and input current profile used in this example is shown in FIG. 8. The input profile of FIG. 8 corresponds to a section of the UDDS (Urban Dynamometer Driving Schedule) cycle with high C-rate. To demonstrate a hybrid electric vehicle (HEV) application with a small battery pack, 5 heterogeneous cells connected in series are considered. The prediction horizon for automotive applications is generally between 10-120 sec. As the prediction horizon increases, the heterogeneity effect worsens. Hence, for testing robustness a prediction horizon of 120 sec is used in this example. FIGS. 9A-9C show the voltage and state responses for the 5 cells subjected to the current input shown in FIG. 8. Parameter heterogeneity is evident.

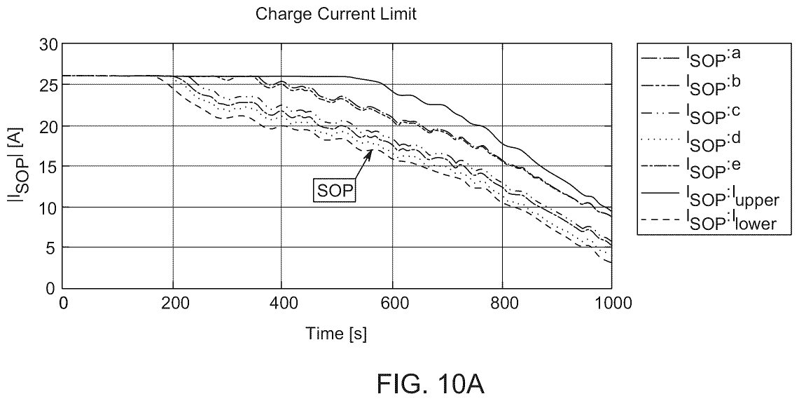

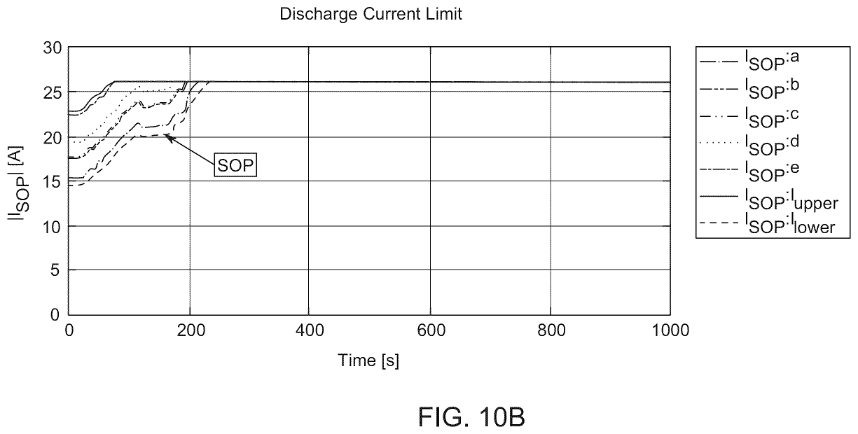

For the given current cycle, the predicted maximum current capability is shown in FIGS. 10A-10B for SOP under both charging and discharging, respectively. The solid lines represent the SOP current values for the 5 individual cells, whereas the dotted line represents the upper and lower SOP current bounds obtained using the interval prediction approach according to the invention. It should be noted that even though the upper and lower bounds are shown, the SOP of the pack is defined by the lower bound as the lower SOP bound ensures safety for all cells.

The maximum safe current in this analysis is taken as 10 C (i.e. 26 A), which equals I^{r} in the modified reference governor. Whenever the SOP algorithm predicts maximum 26 A current, this signifies that the battery pack power is constrained by current limits. In other regions the power is limited by either SOC, voltage or temperature limits. For the current cycle considered, cell SOC, voltage and temperature increase over time. Temperature is expected to increase because the overall process is exothermic. The increasing SOC trend implies that the battery is running through a net charging profile. This is the reason behind the trend observed for SOP charge/discharge in FIGS. 10A-10B.

The battery cells in the simulations start from a low SOC regime. Hence, the charging SOP predicted is high initially. As the battery cell moves to higher SOC ranges, the charging power diminishes. The opposite is true for discharge power prediction. The method according to the invention provides both accuracy and tightness for SOP prediction for an entire pack of heterogeneous cells.

The method according to the present invention advantageously uses interval prediction for SOP prediction. Accurate and tight state interval predictions are obtained, which can be used to compute safe pack power limits. The reference governor used in the invention is applied for obtaining the safe maximum applied current, which ultimately defines SOP. The proposed power estimation method yields accurate and relatively tight bounds, and is scalable with the number of cells in the pack. The scaling can be applied to a battery pack of any number of cells. The cells of the battery pack are treated as an uncertain parameter varying system. For a given input, an interval of a reachable state is predicted rather than focusing on any individual cell or group of cells in the battery system. The amount of calculations thus stays the same for any number of cells.

A second embodiment of the method according to the invention will now be described directed to estimation of the bounds of the state/output trajectory accurately for a pack of cells. Cells in a battery pack can be placed in various series/parallel configurations. A series arrangement for a cell in a battery pack is considered for analysis in this embodiment, as shown in FIG. 2. The coolant temperature across all the cells in assumed constant. The thermal parameters of the cells (C_{c,k}, C_{s,k}, R_{c,k}, R_{s,k}, R_{c,k}) in the second embodiment are also considered heterogeneous and the heat exchange between the cells is also accounted for. Similar to the first embodiment, the safety limits of Table 1 above are used.

Owing to series arrangement the current application in all the cells of the pack is equal, while the voltage response might vary depending on the cell-to-cell heterogeneity. Each cell's thermal dynamics is also affected by the heat exchange with its neighboring cells. The overall cell dynamics in the battery pack is given by equations (1-7) above. The SOP estimation in this embodiment determines the maximum constant current Iₘₐₓ^{dis}, Iₘₐₓ^{ch} for discharge and charge limits respectively, for a chosen prediction time horizon Tₚ. For the safety constraints considered Iₘₐₓ^{dis}, Iₘₐₓ^{ch} can be written as:

$$\{ \begin{matrix}{I}_{max , t}^{dis} = min \{ {i}_{t , {T}_{p}}^{dis , SOC} , {i}_{t , {T}_{p}}^{dis , V} , {i}_{t , {T}_{p}}^{dis , T} , {i}_{t , {T}_{p}}^{dis , I} \} \\ {I}_{max , t}^{ch} = min \{ {i}_{t , {T}_{p}}^{ch , SOC} , {i}_{t , {T}_{p}}^{ch , V} , {i}_{t , {T}_{p}}^{ch , T} , {i}_{t , {T}_{p}}^{ch , I} \}\end{matrix} \qquad ( 47 )$$

Where i_{t,T}_{ₚ}^{SOC}, i_{t,T}_{ₚ}^{dis,V}, i_{t,T}_{ₚ}^{dis,T}, iₘₐₓ^{dis,I} are the maximum constant current pulses that can be applied for Tₚ duration, without violating the SOC, voltage, temperature and current constrains for a given cell. For the battery pack with ‘m’ cells in series these constraints have to hold for all the cells as shown in equations (48-49).

For discharge limits ∀k={1, . . . , m}, t∈[t, t+Tₚ]:

$$\{ \begin{matrix}{I}_{t , {T}_{p}}^{dis , SOC} = max \{ {i}^{dis} \vert {SOC}_{k} ( t ) >= {SOC}_{min} \} \\ {I}_{t , {T}_{p}}^{dis , V} = max \{ {i}^{dis} \vert {V}_{k} ( t ) >= {V}_{min} \} \\ {I}_{t , {T}_{p}}^{dis , T} = max \{ {i}^{dis} \vert {T}_{k} ( t ) <= {T}_{max} \} \\ {I}_{t , {T}_{p}}^{dis , J} = {i}_{max}^{dis}\end{matrix} \qquad ( 48 )$$

Similarly for charge limits:

$$\{ \begin{matrix}{I}_{t , {T}_{p}}^{ch , SOC} = max \{ {i}^{dis} \vert {SOC}_{k} ( t ) <= {SOC}_{max} \} \\ {I}_{t , {T}_{p}}^{ch , V} = max \{ {i}^{dis} \vert {V}_{k} ( t ) <= {V}_{max} \} \\ {I}_{t , {T}_{p}}^{ch , T} = max \{ {i}^{dis} \vert {T}_{k} ( t ) <= {T}_{max} \} \\ {I}_{t , {T}_{p}}^{ch , I} = {i}_{max}^{ch}\end{matrix} \qquad ( 49 )$$

SOP can hence be estimated for the battery pack with n cells in series:

$$SOP : \{ \begin{matrix}{P}^{dis} = n \cdot {I}_{max , t}^{dis} \cdot \underline{V} ( {I}_{max , t}^{dis} ) \\ {P}^{ch} = n \cdot {I}_{max , t}^{ch} \cdot \underline{V} ( {I}_{max , t}^{ch} )\end{matrix} \qquad ( 50 )$$

$$where \underline{V} ( {I}_{max , t}^{dis} ) = min \{ V ( {I}_{max , t}^{dis} ) \vert ∀ \{ 1 , … , m \} , t ∈ [ t , t + {T}_{p} ] \} , \\ \underline{V} ( {I}_{max , t}^{ch} ) = min \{ V ( {I}_{max , t}^{ch} ) \vert ∀ \{ 1 , … , m \} , t ∈ [ t , t + {T}_{p} ] \}$$

SOP Prediction Algorithm

Owing to uncertain parameters and initial condition of the cells, the state of all the cells in a pack can be different, which implies that the operating voltage and temperature of the cells are not uniform. Hence for battery SOP prediction, prediction of the minimum constant current that can take any of the cells/modules in the battery pack to an unsafe condition (SOC, Voltage or temp) is desired. In the second embodiment, the problems related to heterogeneity are circumvented by focusing on evaluation of bounds of state trajectories associated with the cells of the pack, rather than evaluation of states of all/any of the cells. State trajectories represent the evolution of states over time.

The system is defined by the equation 11 above. The trajectories of the system are denoted by ψ. Φ((t; t₀, x₀, p) indicates the state of the system at time t≥t₀ given the initial condition x₀. For the ECMT system defined similar to equation (12) above, all of the sets of states that the system with parameter uncertainty will reach from a given initial condition are determined. This is done by evaluating the upper and lower bound of state trajectories for the ECMT. For a system defined by equation (12) and for the given time range [t₀, t_{f}], initial states [x₀, x̅₀̅], parameter bounds [p, p̅], the reachable set R, at time t_{f} are given by sets of all states the system can take:

R={x(t_{f};t₀,x₀,p)|x₀∈[x₀,x̅₀],p:[t₀,t_{f}]→[p,p̅]} (51)

The reachable set prediction is done by predicting the bound of trajectories of the states [Φt), Φ̅(t)]:

Φ(t;t₀,x₀,p)⊆[Φ(t),Φ̅(t)] (52)

The states bounds for the ECMT are given by:

$$\{ \begin{matrix}\underline{SOC} ( t ) \leq {SOC}_{k} \leq \overline{SOC} ( t ) ; \underline{{V}_{c}} ( t ) \leq {V}_{c , k} \leq \overline{{V}_{c}} ( t ) \\ \underline{{T}_{c}} ( t ) \leq {T}_{c , k} \leq \overline{{T}_{c}} ( t ) ; \underline{{T}_{s}} ( t ) \leq {T}_{s , k} \leq \overline{{T}_{s}} ( t )\end{matrix} \qquad ( 53 )$$

As the OCV is a monotonic function of SOC, the following can also be determined for voltage:

V̅(t)=OCV(S̅O̅C̅(t))+V̅_̅{̅c̅}̅(t)+I(t)R_{0,max},

V(t)=OCV(SOC(t))+V_{c}(t)+I(t)R_{0,min}.

T̅(t)=½(T̅_̅{̅c̅}̅(t)+T̅ₛ̅(t)),T(t)=½(T_{c}(t)+Tₛ(t)). (54)-(56)

For SOP evaluation during charging, the following constraints are used:

Iₘₐₓ:V̅(t)≤Vₘₐₓ;S̅O̅C̅(t)≤SOCₘₐₓ;T̅(t)≤Tₘₐₓ (57)

Similarly for discharging:

Iₘₐₓ:Vₘᵢₙ≤V(t);SOCₘᵢₙ≤SOC(t);Tₘᵢₙ≤T(t). (57)

Evaluation of these bounding system trajectories substantially simplifies the SOP prediction with heterogeneity, as the focus is only on evaluation of bounding state trajectories that encompass all of the cells rather than a state determination of any individual cell. This is a major advantage as increasing the number of heterogeneous cells has no impact in computation effort or memory required for SOP evaluation.

Similar to the first embodiment, the interval predictor is used to predict the state/output bounds for a given parametric uncertainty and input current, which when combined with the modified reference governor (MRG) is used in the SOP prediction. The second embodiment includes reachability algorithm in combination with the MGR In particular, the reachability algorithm predicts state bounds for a given input current while MGR iteratively computes the maximum current that keeps the states and outputs with the safe operating window.

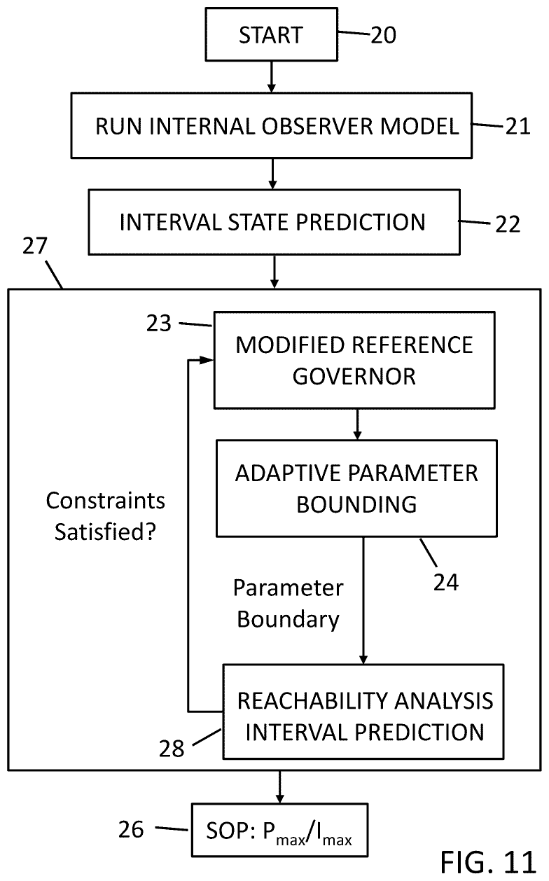

FIG. 11 shows the interaction of the reachability algorithm and with MRG. In the second embodiment reachability analysis is performed in Step 28 to generate battery parameter boundaries. These boundaries are compared to the constraint value y and an output indicating whether the constraints are satisfied is fed back and then used by MRG 23 to generate the current I. The process continues until the maximum value of a is obtained.

Interval Reachability Analysis

Reachability deals with prediction of states that a given system can attain in a finite time horizon from a given initial condition. As stated, the ECMT model in our study is a system with uncertainty in its parameters as well as initial condition. The prediction of tight estimates state bounds is essential for accuracy. Unlike state observers where control over observer gain gives the flexibility to have a stable as well as robust state estimate, state predictor's stability, robustness and accuracy is algorithm dependent. See Leurent E, Efimov D, Raissi T, Perruquetti W., Interval prediction for continuous-time systems with parametric uncertainties, In 2019 IEEE 58th Conference on Decision and Control (CDC) 2019 Dec. 11 (pp. 7049-7054), the contents of which are herein incorporated by reference; and Efimov, supra.

Monotonic systems are simplified ‘cooperative’ systems, whose state trajectories preserve a partial order. A system defined by equation (12) can be considered a monotonic system if the following inequalities hold for any pair of x₀, x′₀∈ [symbol] ^{x} and p, p′∈ [symbol] ^{p}:

x₀≤x′₀,p≤p′⇒Φ(t_{f};t₀,x₀,p)≤Φ(t_{f};t₀,x′₀,p) (59)

For the above condition to hold, there are strict conditions on the sign-stability and structure of the Jacobian of the system (see Meyer P J, Devonport A, Arcak M. Interval Reachability Analysis: Bounding Trajectories of Uncertain Systems with Boxes for Control and Verification, Springer International Publishing; 2021, the contents of which are herein incorporated by reference), which limit the classification of a number of systems into the monotonic category. This is the case for the ECMT system in the second embodiment where, having specific parameter uncertainty, the required sign structure is violated. A mixed monotone system is a generalized version of monotonic system, which can be decomposed into a monotonically increasing part and a monotonically decreasing part. A wider class of system, which generally is any continuous-time dynamical system with a Lipschitz continuous vector field, falls under the category of mixed monotonic. This facilitates the application of valuable and robust reachability set theorems of monotonic systems to broader variety of systems.

Definition 1: The system defined, is called a mixed monotone system, if the mapping f: R×R^{x}×R^{p}−→R^{x} can be decomposed into g: R×R^{x}×R^{p}×R^{x}×R^{p}→R^{x} such that the following conditions are satisfied Meyer, supra:
1) For all x∈R^{x} and p∈R^{p}, f is embedded on the diagonal of g, i.e., g(t, x, p, x, p)=f(t, x, p)
2) For all i, j∈{1, . . . , nₓ}, k={1, . . . , nₚ} and i≠j, g is monotonic increasing in terms of the first pair of argument, i.e., x₁≥x₂⇒g(t, x₁, p, x′, p′)≥g(t, x₂, p, x′, p′) and p₁≥p²⇒g(t, x, p₁, x′, p′)≥g(t, x, p₂, x′, p′):

$$\frac{\partial {g}_{i} ( t , x , p , \hat{x} , \hat{p} )}{\partial {x}_{j}} \geq 0 , \frac{\partial {g}_{i} ( t , x , p , \hat{x} , \hat{p} )}{\partial {p}_{k}} \geq 0 , \qquad ( 60 )$$

3) For all i, j∈{1, . . . , nₓ} and k=(1, . . . , nₚ) and i≠j, g is monotonic decreasing in terms of the first pair of argument, i.e., x₁≥x₂⇒g(t, x₁, p, x′, p′)≤g(t, x₂, p, x′, p′) and p₁≥p₂⇒g(t, x, p₁, x′, p′)≤g(t, x, p₂, x′, p′):

$$\frac{\partial {g}_{i} ( t , x , p , \hat{x} , \hat{p} )}{\partial {\hat{x}}_{j}} \leq 0 , \frac{\partial {g}_{i} ( t , x , p , \hat{x} , \hat{p} )}{\partial {\hat{p}}_{k}} \leq 0 , \qquad ( 61 )$$

Mathematically, the applicability of the approach can be examined by checking the boundedness of the Jacobian matrices. The checking determines whether there exist matrices Lₓ and Lₚ such that adding them in the Jacobian matrices Jₓ and Jₚ respectively results in sign stable matrices over the time, in state and parameter ranges under consideration.

Assumption 1: Given an invariant state space X⊆ [symbol] ⁿ^{ₓ}, there exists Lₓ∈ [symbol] ⁿ^{ₓ}^{×n}^{ₓ}, such that for all i, j∈1, . . . , nₓ with j≠i, either

|Jₓᵢⱼ(t,x,p)+Lₓᵢⱼ≥0,∀t∈[t₀,t_{f}],x∈X,p∈[p,p̅],

or

Jₓᵢⱼ(t,x,p)+Lₓᵢⱼ≥0,∀t∈[t₀,t_{f}],x∈X,p∈[p,p̅],

and there exists Lₚ∈ [symbol] ⁿ^{ₓ}^{×n}^{ₚ}, such that for all i∈1, . . . ,nₓ and k∈1, . . . ,nₚ:

Jₚᵢₖ(t,x,p)+Lₚᵢⱼ≥0,∀t∈[t₀,t_{f}],x∈X,p∈[p,p̅],

or

Jₚᵢₖ(t,x,p)+Lₓᵢⱼ≥0,∀t∈[t₀,t_{f}],x∈X,p∈[p,p̅],

The decomposition function is defined as:

gᵢ(t,x,p,\hat{x},\hat{p})=fᵢ(t,ξⁱ,nⁱ)+|L_{xi*}|(x−\hat{x})+|L_{pi*}|(p−\hat{p}) (62)

where state ξⁱ∈ [symbol] ⁿ^{ₓ} and parameter πⁱ∈ [symbol] ⁿ^{ₚ} are defined below based on the sign of the elements of the shifting matrices Lₓ and Lₚ in Assumption 4.1, and L_{xi*}∈ [symbol] ^{1×n}^{ₓ} and L_{pi*}∈ [symbol] ^{1×p} are the row vectors representing the i^{th} row of matrices Lₓ and Lₚ, respectively. The elements ξⁱ=[ξ₁ⁱ; . . . ; ξₙₓⁱ] match the elements of either x or J depending on the signs in the shifting matrix Lₓ, where for all j∈1, . . . , nₓ:

$${ξ}_{j}^{i} : \{ \begin{matrix}{x}_{j} & if {L}_{xij} \geq 0 , \\ {\hat{x}}_{j} & if {L}_{xij} \leq 0\end{matrix} \qquad ( 63 )$$

$$Similarly :$$

$${π}_{j}^{i} : \{ \begin{matrix}{p}_{k} & if {L}_{pij} \geq 0 , \\ {\hat{p}}_{k} & if {L}_{pij} \leq 0\end{matrix} \qquad ( 64 )$$

The resulting embedded stem becomes:

$$( \begin{matrix}\hat{x} \\ \hat{x}\end{matrix} ) = h ( t , x , p , \hat{x} , \hat{p} ) = ( \begin{matrix}g ( t , x , p , \hat{x} , \hat{p} ) \\ g ( t , \hat{x} , \hat{p} , x , p )\end{matrix} ) \qquad ( 65 )$$

Under Assumption 1, and the system definition according to equations (60-61), the over-approximation of the reachable set R(t_{f}; t₀, [x,x̅], [p,p̅]) of equation (12) can be defined by the interval: [Φ_{1 . . . n}_{ₓ}^{h}(t_{f}; t₀; x, p, x̅, p̅), Φₙ_{ₓ}_{+1 . . . 2n}_{ₓ}^{h}(t_{f}; t₀; x, p, x̅, p̅)].

Reachability Analysis for Battery Power Prediction

For the ECMT model described above, power prediction is done utilizing the reachability analysis method described for the mixed monotonic system. The model equations show that there are two states, i.e., (SOC, V_{c}) that represent the electric part of the model for each cell. The thermal part on the other hand, though, is also represented by two states T_{c}, Tₛ, but the dynamics for each cell T_{s,x} are linked with the dynamics of the neighboring cells in contact (T_{s,k-1},T_{s,k+1}). This complicates the analysis as the objective is to have one single representation of the state of all the cells in the pack and avoid the state prediction for individual cells. To this extent, therefore the following over-approximation for evaluating reachability is introduced.

Thermal over approximation: the term

$$\frac{{T}_{s , k - 1} ( t ) + {T}_{s , k + 1} ( t ) - 2 {T}_{s , k} ( t )}{{R}_{cc}}$$

represents conductive heat transfer between cells, which can be eliminated considering the following:
1) For the hottest cell in the pack, this term would only provide cooling, thereby lowering its temperature. Assuming the hottest cell to be surrounded by cells equally hot i.e. (T_{s,k-1}=T_{s,k+1}=T_{s,k}), is an over approximation in calculation of the upper temperature limit of the cells.
2) For the coldest cell in the pack, this term would only provide heating, thereby increasing its temperature. Assuming the coldest cell to be surrounded by cells equally cold i.e. (T_{s,k-1}=T_{s,k+1}=T_{s,k}) is an over approximation in calculation of the lower temperature limit of the cells.

The above approximation (T_{s,k-1}=T_{s,k+1}=T_{s,k}) eliminates the cell to cell conductive term and reduces the model equations (1-6) for cells to the simpler form of equation (66) below. Hence, considering above over approximations, the ECMT model can be written as:

$$[ \begin{matrix}\dot{{SOC}_{k}} \\ \dot{{V}_{c , k}} \\ \dot{{T}_{c , k}} \\ \dot{{T}_{s , k}}\end{matrix} ] = [ \begin{matrix}\frac{I}{{Q}_{k}} \\ - \frac{1}{{R}_{1 , k} C} {V}_{c} + \frac{1}{{C}_{k}} I \\ \frac{1}{{C}_{c , k}} ( {I}_{k} * ( {V}_{c} + {I}_{k} {R}_{0 , k} ) ) + \frac{1}{{R}_{c , k} {C}_{c , k}} ( {T}_{s , k} - {T}_{c , k} ) \\ \frac{1}{{R}_{u , k} {C}_{s , k}} ( {T}_{f} - {T}_{s} ) - \frac{1}{{R}_{c , k} {C}_{s , k}} ( {T}_{s} - {T}_{c} )\end{matrix} ] \qquad ( 66 )$$

The states considered in the model for each cell k are, x=[SOC, V_{c}, T_{c}, Tₛ]. The cell to cell variation is caused due to:
1) Parametric uncertainty in electric model i.e., R_{0,k}, R_{1,k}, Cₖ, Qₖ, leading to cells operating at different states. Further, the parameters R₀, R₁, C are state dependent which causes additional enhancement in state variations across the cells.
2) The temperature variations in cells are caused by firstly, because of heterogeneity in thermal parameters i.e. {R_{c}, Rᵤ, C_{c}, Cₛ}. Secondly, variation in electric dynamics due to ohmic and overpotential losses, produces non-uniform heat generation further increasing temperature differences.

ECMT has uncertainty in 8 model parameters, as stated above, and the uncertain parametric set considered for the reachability analysis is taken as follows:

$$P = [ \begin{matrix}\frac{1}{Q} & \frac{1}{RC} & \frac{1}{C} & {R}_{0} & \frac{1}{{R}_{c} {C}_{c}} & \frac{1}{{R}_{u} {C}_{s}} & \frac{1}{{R}_{c} {C}_{s}} & \frac{1}{{C}_{c}}\end{matrix} ] ∈ {ℝ}^{8} \qquad ( 67 )$$

The model parameters are combined and the resulting uncertain set of parameters considered for the reachability analysis is stated above. Combining of the model parameters into the set of parameters mentioned above produces a system that can be represented as mixed monotonic. The result is:

$$[ \begin{matrix}{\hat{x}}_{1} \\ {\hat{x}}_{2} \\ {\hat{x}}_{3} \\ {\hat{x}}_{4}\end{matrix} ] = [ \begin{matrix}{p}_{1} * I \\ - {p}_{2} {x}_{2} + {p}_{3} I \\ {p}_{8} ( I * ( {x}_{2} + I * {p}_{4} ) ) + {p}_{5} ( {x}_{4} - {x}_{3} ) \\ {p}_{6} ( {T}_{f} - {x}_{4} ) - {p}_{7} ( {x}_{4} - {x}_{3} )\end{matrix} ] \qquad ( 68 )$$

To check the application of mixed monotonicity reachability method in the ECMT system, the focus is on finding matrices Lₓ and Lₚ such that Jₓ+Lₓ (apart from diagonal element) and Jₚ+Lₚ are sign stable (constant sign) at all time, the in range of states and input considered. This translates to checking the boundedness of the Jacobian matrixes.

$${J}_{x} = [ \begin{matrix}\frac{\partial {f}_{1}}{\partial {x}_{j}} & \frac{\partial {f}_{1}}{\partial {x}_{2}} & \frac{\partial {f}_{1}}{\partial {x}_{3}} & \frac{\partial {f}_{1}}{\partial {x}_{4}} \\ \frac{\partial {f}_{2}}{\partial {x}_{1}} & \frac{\partial {f}_{2}}{\partial {x}_{2}} & \frac{\partial {f}_{2}}{\partial {x}_{3}} & \frac{\partial {f}_{2}}{\partial {x}_{4}} \\ \frac{\partial {f}_{3}}{\partial {x}_{1}} & \frac{\partial {f}_{3}}{\partial {x}_{2}} & \frac{\partial {f}_{3}}{\partial {x}_{3}} & \frac{\partial {f}_{3}}{\partial {x}_{4}} \\ \frac{\partial {f}_{4}}{\partial {x}_{1}} & \frac{\partial {f}_{4}}{\partial {x}_{2}} & \frac{\partial {f}_{4}}{\partial {x}_{3}} & \frac{\partial {f}_{4}}{\partial {x}_{4}}\end{matrix} ] = [ \begin{matrix}0 & 0 & 0 & 0 \\ 0 & - {p}_{2} & 0 & 0 \\ 0 & {p}_{8} I & - {p}_{5} & {p}_{5} \\ 0 & 0 & {p}_{7} & - ( {p}_{6} + {p}_{7} )\end{matrix} ] \qquad ( 69 )$$

The above matrix Jₓ is always sign stable both for charge and discharge case. All parameters are nonnegative i.e. p≥0, hence

$$when I \geq 0 , sign ( {J}_{x} ) = [ \begin{matrix}0 & 0 & 0 & 0 \\ 0 & - & 0 & 0 \\ 0 & + & - & + \\ 0 & 0 & - & -\end{matrix} ] \\ when I \leq 0 , sign ( {J}_{x} ) = [ \begin{matrix}0 & 0 & 0 & 0 \\ 0 & - & 0 & 0 \\ 0 & - & - & + \\ 0 & 0 & - & -\end{matrix} ] \\ Similarly , ] \qquad ( 70 )$$

$${J}_{p} = [ \begin{matrix}\frac{\partial {f}_{1}}{\partial {p}_{1}} & \frac{\partial {f}_{1}}{\partial {p}_{2}} & \frac{\partial {f}_{1}}{\partial {p}_{3}} & \frac{\partial {f}_{1}}{\partial {p}_{4}} & \frac{\partial {f}_{1}}{\partial {p}_{5}} & \frac{\partial {f}_{1}}{\partial {p}_{6}} & \frac{\partial {f}_{1}}{\partial {p}_{7}} & \frac{\partial {f}_{1}}{\partial {p}_{8}} \\ \frac{\partial {f}_{2}}{\partial {p}_{1}} & \frac{\partial {f}_{2}}{\partial {p}_{2}} & \frac{\partial {f}_{2}}{\partial {p}_{3}} & \frac{\partial {f}_{2}}{\partial {p}_{4}} & \frac{\partial {f}_{2}}{\partial {p}_{5}} & \frac{\partial {f}_{2}}{\partial {p}_{6}} & \frac{\partial {f}_{2}}{\partial {p}_{7}} & \frac{\partial {f}_{2}}{\partial {p}_{8}} \\ \frac{\partial {f}_{3}}{\partial {p}_{1}} & \frac{\partial {f}_{3}}{\partial {p}_{2}} & \frac{\partial {f}_{3}}{\partial {p}_{3}} & \frac{\partial {f}_{3}}{\partial {p}_{4}} & \frac{\partial {f}_{3}}{\partial {p}_{5}} & \frac{\partial {f}_{3}}{\partial {p}_{6}} & \frac{\partial {f}_{3}}{\partial {p}_{7}} & \frac{\partial {f}_{3}}{\partial {p}_{8}} \\ \frac{\partial {f}_{4}}{\partial {p}_{1}} & \frac{\partial {f}_{4}}{\partial {p}_{2}} & \frac{\partial {f}_{4}}{\partial {p}_{3}} & \frac{\partial {f}_{4}}{\partial {p}_{4}} & \frac{\partial {f}_{4}}{\partial {p}_{5}} & \frac{\partial {f}_{4}}{\partial {p}_{6}} & \frac{\partial {f}_{4}}{\partial {p}_{7}} & \frac{\partial {f}_{4}}{\partial {p}_{8}}\end{matrix} ] =$$

$$[ \begin{matrix}I & 0 & 0 & 0 & 0 & 0 & 0 & 0 \\ 0 & - {x}_{2} & I & 0 & 0 & 0 & 0 & 0 \\ 0 & 0 & 0 & {p}_{8} {I}^{2} & ( {x}_{4} - {x}_{3} ) & 0 & 0 & I ( {x}_{2} + I . {p}_{4} ) \\ 0 & 0 & 0 & 0 & 0 & ( {T}_{f} - {x}_{4} ) & - ( {x}_{4} - {x}_{3} ) & 0\end{matrix} ]$$

To check the sign of the Jₚ matrix, a closer analysis is required as now state values are involved in sign calculation.

When charging, I≥0, V_{c}=x₂≥0 and \dot{Q}=I(V_{c}+IR₀)≥0. Similarly, while discharging, I≤0, V_{c}=x₂≤0 and \dot{Q}=I(V_{c}+IR₀)≥0. As \dot{Q}≥0 both for charging and discharging conditions, i.e. the cell is generating heat, the core temperature of the cell is going to be higher than surface temperature which in turn is higher than the temperature of the coolant, i.e. T_{c}>Tₛ(x₃>x₄) and Tₛ≥T_{f}(x₄>T_{f}). When:

$$I \geq 0 sign ( {J}_{p} ) = [ \begin{matrix}I & 0 & 0 & 0 & 0 & 0 & 0 & 0 \\ 0 & - & + & 0 & 0 & 0 & 0 & 0 \\ 0 & 0 & 0 & + & - & 0 & 0 & + \\ 0 & 0 & 0 & 0 & 0 & - & + & 0\end{matrix} ] \\ I \leq 0 sign ( {J}_{p} ) = [ \begin{matrix}I & 0 & 0 & 0 & 0 & 0 & 0 & 0 \\ 0 & + & - & 0 & 0 & 0 & 0 & 0 \\ 0 & 0 & 0 & + & - & 0 & 0 & + \\ 0 & 0 & 0 & 0 & 0 & - & + & 0\end{matrix} ]$$

As the Jacobians Jₓ and Jₚ themselves are sign stable, in both charging and discharging conditions respectively, the reachability method for mixed monotone system can be applied here. Following the interval prediction algorithm mentioned above, preposition 1 is used for reachability set evaluation. This is done utilizing the Matlab toolbox, TIRA as described in Perez H E, Hu X, Dey S, Moura S J. Optimal charging of Li-ion batteries with coupled electro-thermal-aging dynamics, IEEE Transactions on Vehicular Technology, 2017 Mar. 1; 66(9):7761-70, the content of which are herein incorporated by reference.

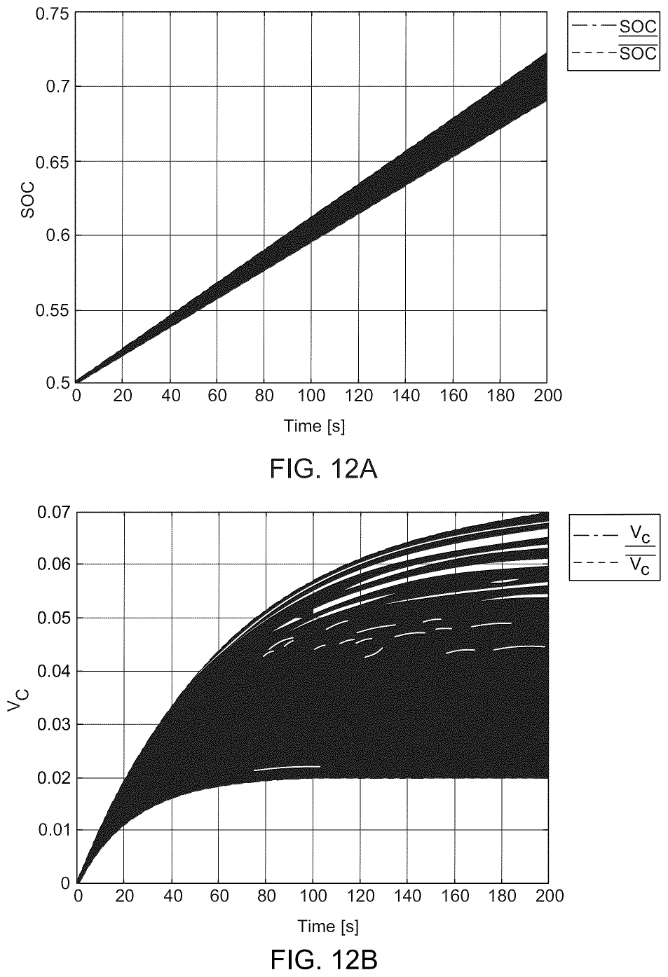

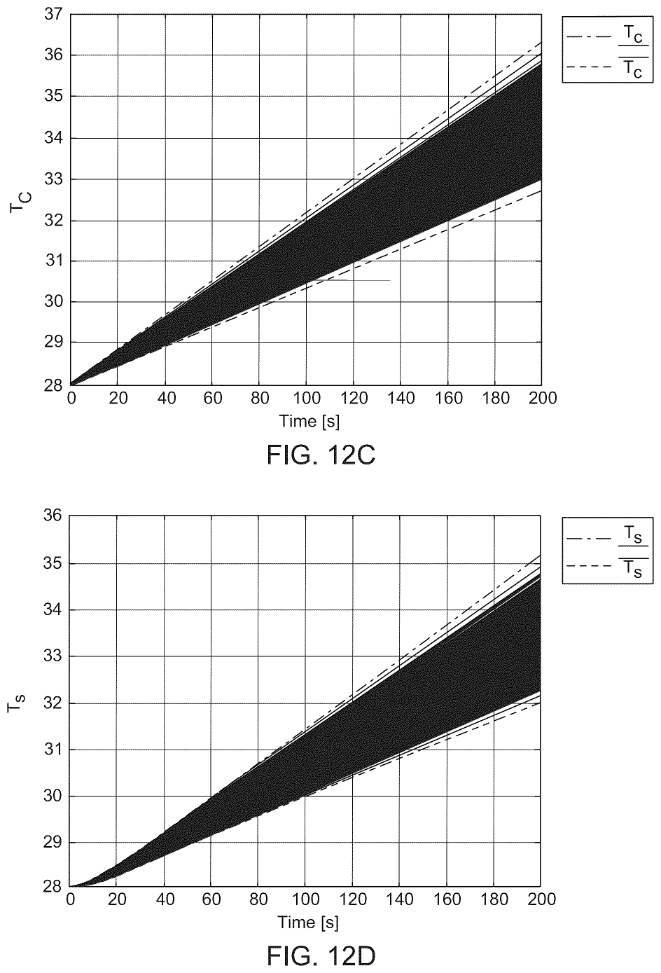

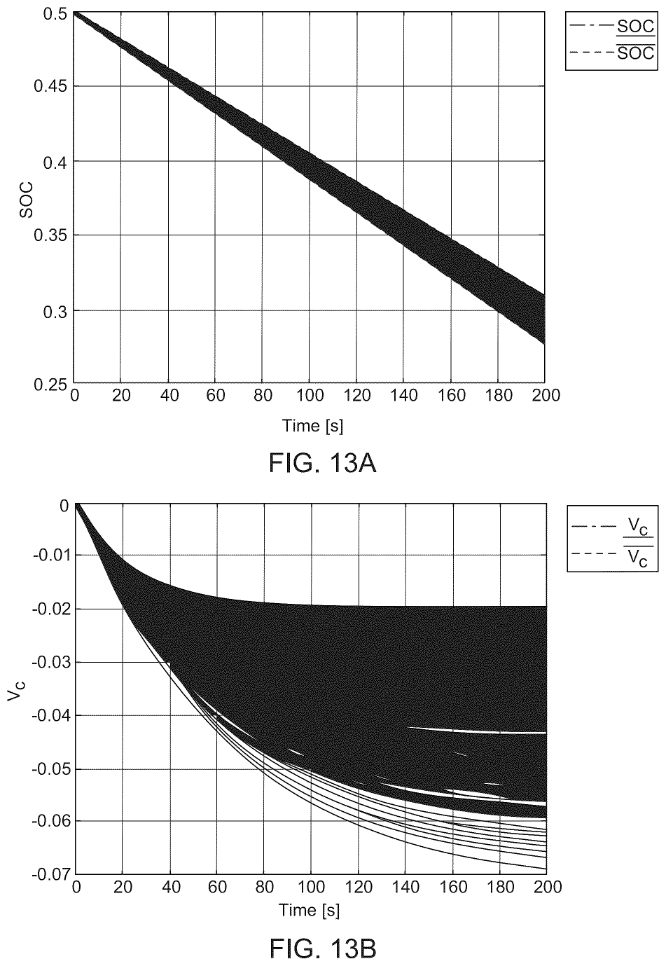

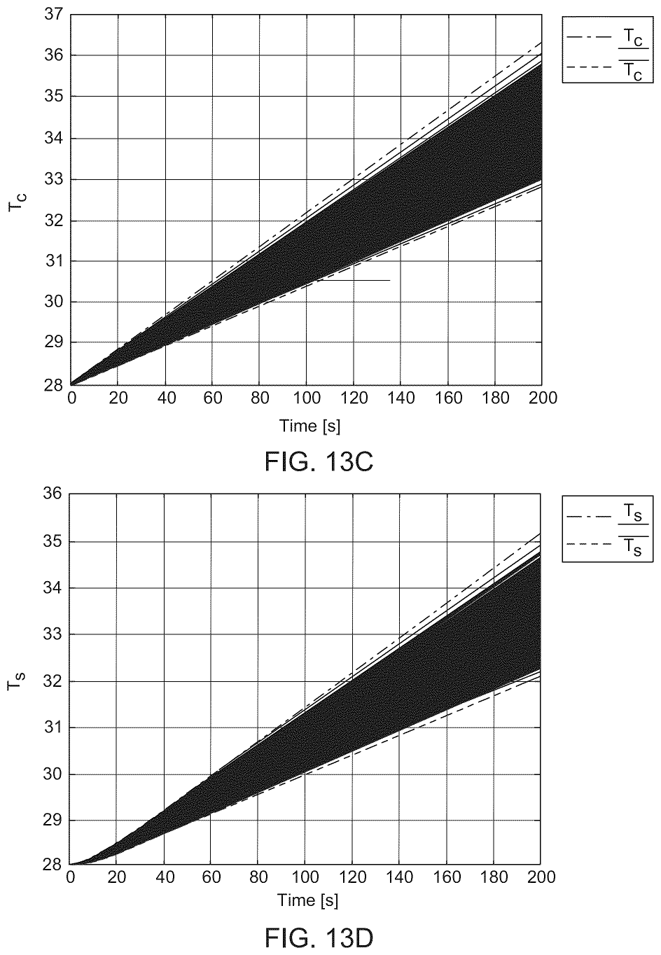

FIGS. 12A-12D and 13A-13D show the results of interval prediction for the ECMT states of charging and discharging, respectively, starting from the given initial condition for a constant current magnitude of +/−10 A (3.8 C), with the following heterogeneity:
1) 10% variation in capacity
2) ±20% variation in electrical parameters
3) ±5% Heterogeneity within thermal parameters

The results show the state evolution over 200 sec. The lighter dashed lines in figures represent the upper and lower bounds of the state predicted over the time horizon. To verify the accuracy and tightness of the predicted bounds, 1000 simulations were performed with a random set of parameters chosen within the defined uncertainty window. The solid black lines in the figures are the resulting state evolution for the simulations, when a random set of parameters is chosen for simulation. FIGS. 12A-12D and 13A-13D verify the tightness and accuracy of state bounds, against state evolution observed for 1000 random parameter simulations.

With the ability of the method according to the invention to accurately predict the state bound for the uncertain LPV (ECMT) system, for a given current magnitude, with tight over-approximations, the remaining part of SOP estimation is maximum safe current prediction. This is accomplished using the Modified Reference Governor, as explained above.

Modified Reference Governor

The MRG used in the second embodiment is that shown in FIG. 7 and described in equations 43-44. The reference current I^{r} is typically a constant value, and α∈[0, 1] is the scaling factor that is evaluated to determine I(t). Integration of MGR with reachability analysis is shown in FIG. 7. The input to MGR is reference current I^{r}, which is chosen as the maximum current limit of the cell. The output of MGR is an attenuated current signal I(t), which becomes the input of reachability algorithm. For the given input current I(t), reachability algorithm predicts the bounds of state and output trajectories. The bounds of state and output trajectories are then the checked with the safety constraints of the cell and then a binary output, i.e., whether the safety constraints are satisfied or not, is fed back to the MGR. The process continues until the maximum value of a is obtained. As in the first embodiment, the MRG and interval predictor are combined in the second embodiment to provide the SOP algorithm for the battery pack.

Interval Observer

Accuracy of SOP prediction is measured by the tightness of the predicted state bounds. Two important factors affecting tightness of predicted state bounds are over-approximations in interval prediction method and the over approximations in the initial conditions. Any slack in initialization of state intervals bounds will be translated in the over-approximations in the entire state trajectories. Therefore, for precise initialization of state intervals the concept of interval observer (see Zhang, supra) is applied, similar to the first embodiment.

Adaptive Parameter Bounding

Adaptive parameter bounding is a feature added to the SOP algorithm to increase the accuracy of the algorithm. One of the inputs of the reachability algorithm is parameter bounds. As mentioned above, the ECM parameters are uncertain as well as parameter dependent. Hence setting proper parameter bounds is complicated. Taking the extreme values of parameters from the entire ECM parameter map would result in conservative state bounds.

Adaptive parameter bounding is a way of choosing the appropriate tighter parameter bound that would be the input to state bound prediction model (reachability). The adaptive parameter bounding described above for the first embodiment is used in the second embodiment.

### Examples

The power prediction accuracy of the SOP algorithm presented is applicable to different profiles and applications. The application can range from small HEV battery packs to large stationary grid storage. In both cases, accurate power prediction is critical. For HEV, the instantaneous power estimates determine the accelerating capability of the vehicle, while for grid energy storage it determines the capacity of the energy storage system to keep up with energy demand. Even though the definition of SOP remains same in both these applications, the manner in which SOP is determined varies.

In HEV application, the number of cells in series is far less than the number of cells that make up grid storage. HEVs are built to be power intensive, hence the cycle that a HEV battery goes through is high C-rate, high frequency currents (see Mitchell I M, Bayen A M, Tomlin C J. A time-dependent Hamilton-Jacobi formulation of reachable sets for continuous dynamic games. IEEE Transactions on automatic control. 2005 Jul. 11; 50(7):947-57, the contents of which are herein incorporated by reference). Grid energy storage on the other hand deals with low to moderate C-rate, with low current fluctuations. The power prediction of HEV is done for the prediction horizon of 10-120 sec (instant vehicle acceleration), while for grid application the prediction horizon would be in the range of 0.5-1 hr (hourly power demand). The SOP algorithm developed for the heterogeneous series cell system is tested for both the applications (HEV and grid) to confirm its robustness and versatility across wide-ranging applications. For both applications the battery pack is considered to be made up of same type of cells, i.e. an NMC cell with 2.6 Ah nominal capacity

Case 1: Small HEV Pack

To demonstrate an example of a small battery pack for HEV application, a battery pack made up of 5 heterogeneous cells connected in series is considered. The parametric heterogeneity is considered uniformly distributed around nominal values. 20% variation is considered in the ECM parameters R₀, R₁ and C, while 10% variation is considered cell capacity (Q) and 5% variation is considered in thermal parameters Rᵤ, R_{c}, C_{c} and Cₛ. The prediction horizon for automotive application in literature is taken between 10-120 sec, where increasing the prediction horizon worsens the heterogeneity effect. Hence for testing robustness 120 sec is used. The maximum safe current application considered is taken as 10 C i.e. 26 A for the cells. This value i.e. 10 C is chosen as I^{r} in the MGR. Whenever the SOP algorithm predicts maximum 26 A current, this signifies that the power of the battery pack is constrained by current limits. In other regions the power is limited by either SOC, voltage or temperature limits.

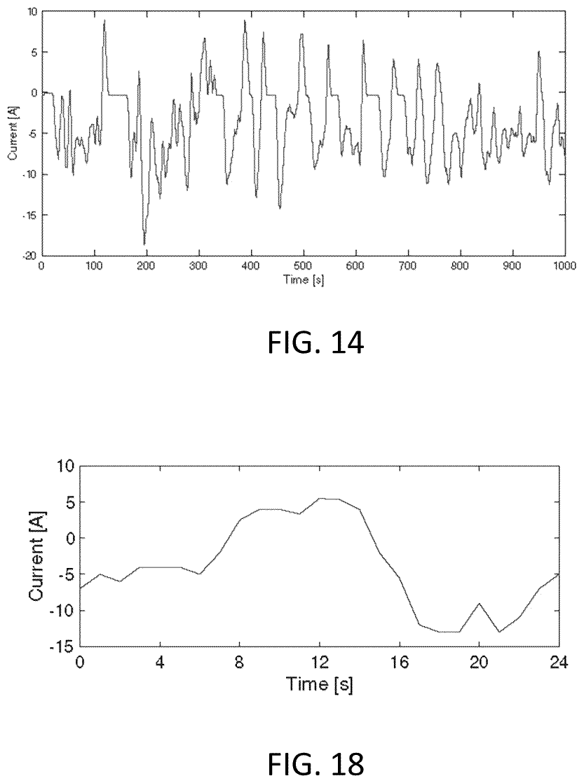

A section of a current profile for a scaled-up UDDS cycle with high C-rate is used for the analysis (FIG. 14). For the cycle considered, cell SOC, voltage and temperature increase over time. Temperature is expected to increases as overall the process is exothermic. Due to the heterogeneity considered, the state of the cells in the pack is different from one another.

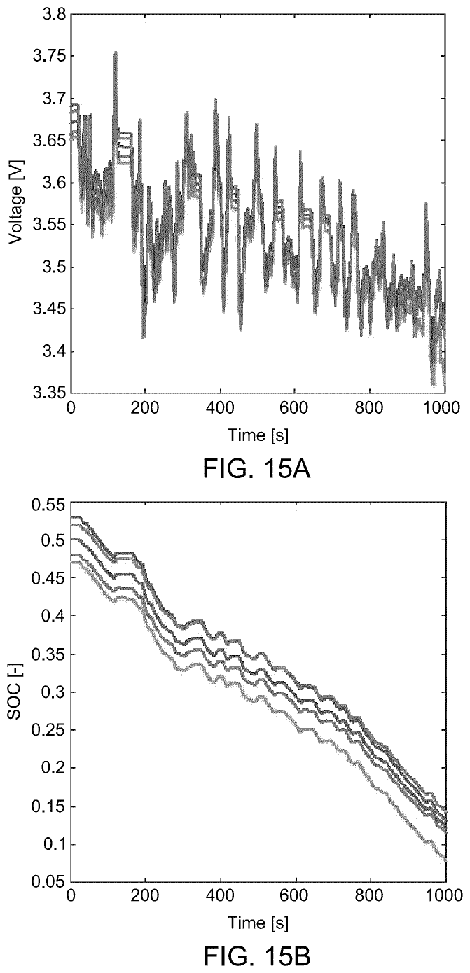

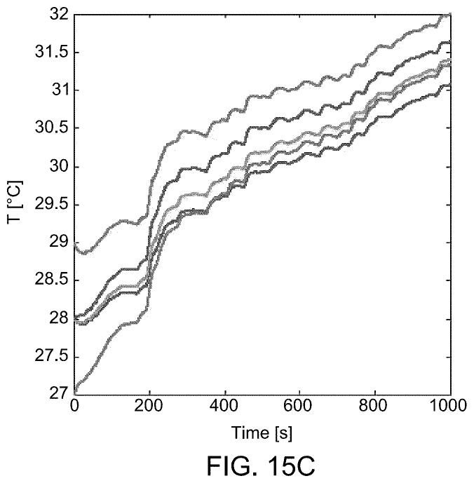

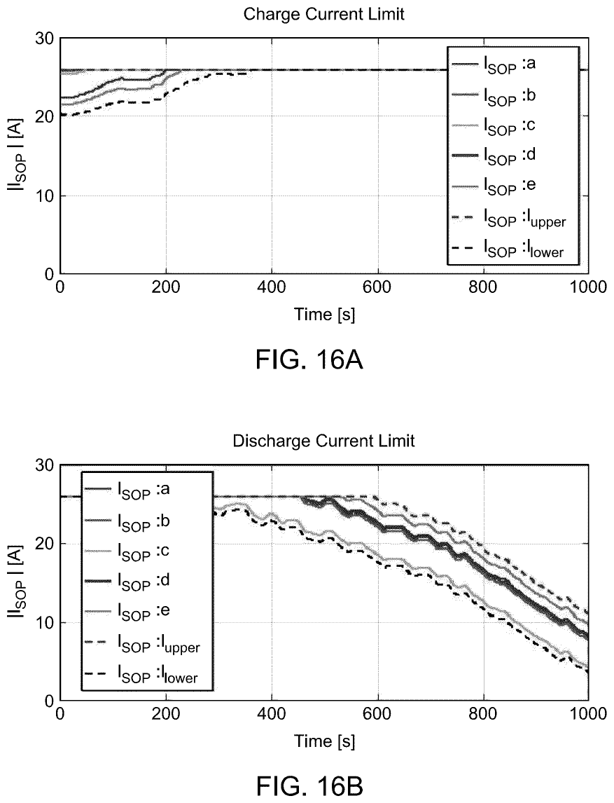

FIGS. 15A-15C show the evolution of the voltage response and the state dynamics of the 5 cells. Both parameter and initial condition heterogeneity is considered here. As the input cycle is an overall discharging cycle, the SOC and voltage have a generally decreasing trend. FIGS. 16A-16B show the charging and discharging prediction. SOP (charge and discharge) current, of the battery cells is shown by solid lines, while the bounds of charge/discharge current obtained using reachability analysis is shown by dashed lines. The SOP charge current predicted has a decreasing trend while the SOP discharge current has a decreasing trend. This is because the cells are undergoing an overall discharging cycle. Even though both upper and lower bounds of SOP current magnitudes are obtained in this process, the lower bound is used to define SOP. This is because when according to the defined SOP for the pack, SOP is the maximum current that all the cells in a pack can sustain without violating any safety constrains. Hence the lower predicted bound will be the maximum safe current for the entire battery pack. The tightness of the lower bound prediction for SOP shows the preciseness of the algorithm.

Case 2: Grid Storage

The algorithm is also tested for the case of grid energy storage, where the prediction problem is scaled up by considering a large number of cells connected in a series-parallel arrangement. In this example, the Tesla Powerwall (https://www.tesla.com/powerwall) is considered as the specification for the stationary energy storage system. The Powerwall also uses NMC chemistry, though the cell specification might be different. The Powerwall is here considered be to made of the same 2.6 Ah nominal capacity NMC cells, with similar heterogeneity that we used in Case 1 (HEV). The Powerwall energy capacity and internal battery voltage is specified to be 13.5 kWh and 50 V respectively. To meet this specification the Powerwall is assumed to be made of 14 modules connected in series, where each module is made up of 107 cells in parallel (14 s/107p, cell configuration). For the analysis, one module (107p cells) is considered as 1 unit and focus on the heterogeneity in the modules rather than the cells. The parameters of the module are scaled considering 107 2.6 Ah cells connected in parallel (Yao S, Liu W, Cheng J, Shen Y., Series-parallel grouping modeling simulation and experimental analysis of zinc-nickel single flow batteries, Journal of Renewable and Sustainable Energy, 2018 May 28; 10(3):034105, the contents of which are herein incorporated by reference). The prediction horizon is chosen in hours, rather than in seconds for the HEV example. The configuration scales to:
1) 14 modules/units in series
2) Module capacity 270 Ah (heterogeneous cells)
3) 1 hour prediction horizon

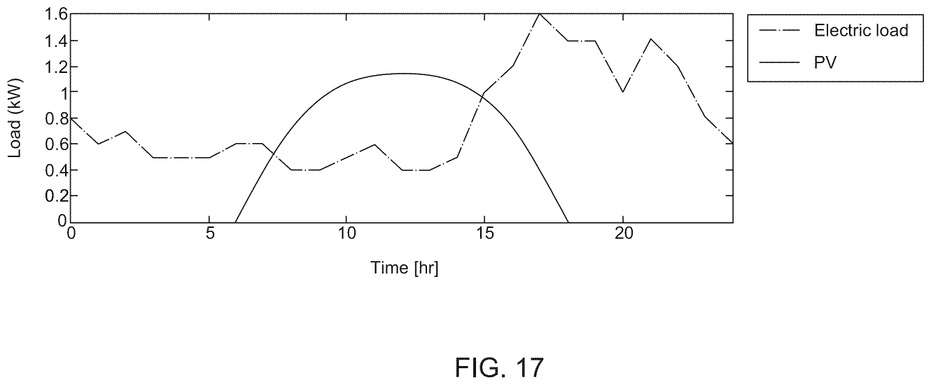

The Powerwall example is directed to a residential household load which has solar PV installed. The load profile obtained from household electric load data (see Jahangiri M, Nematollahi O, Sedaghat A, Saghafian M, Techno-economical assessment of renewable energies integrated with fuel cell for off grid electrification: A case study for developing countries. Journal of Renewable and Sustainable Energy, 2015 Mar. 15; 7(2):023123, the contents of which are herein incorporated by reference) and the solar PV power production data for an average day for California (National Renewable Energy Laboratory). FIG. 16 shows the electric load demand and PV electric generation considered. It is assumed the total overall load of the household (household electric load-PV production) is sustained by the Powerwall. Given the specification of the Powerwall, FIG. 18 shows the current profile that the Powerwall will undergo for the load profile shown in FIG. 17. When the solar PV is producing electricity higher than the energy consumption of the household is when the Powerwall is charging, and the rest of the time the Powerwall goes through discharging to sustain the electric demand of the household.

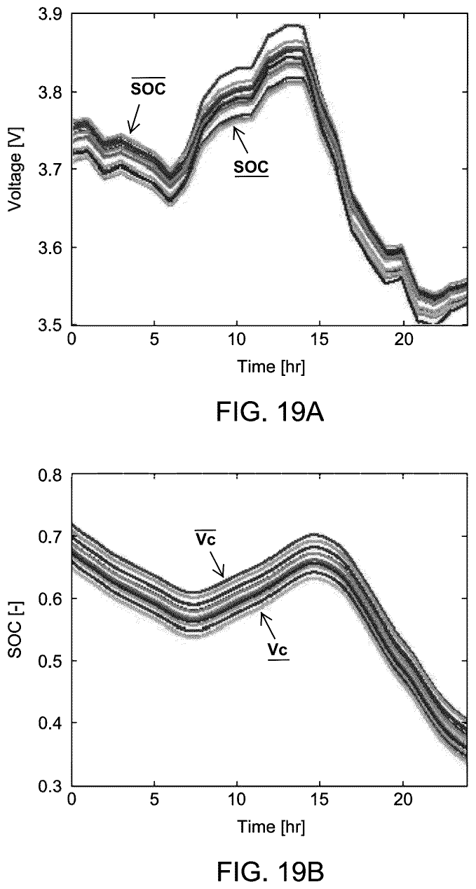

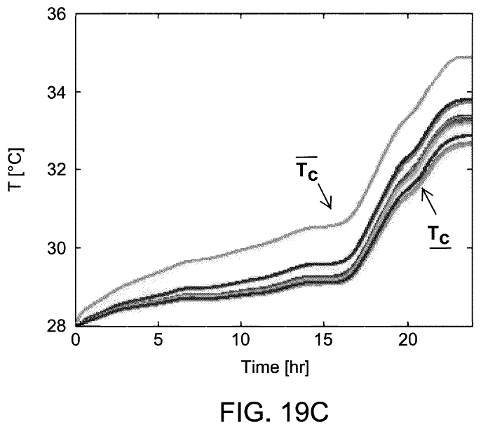

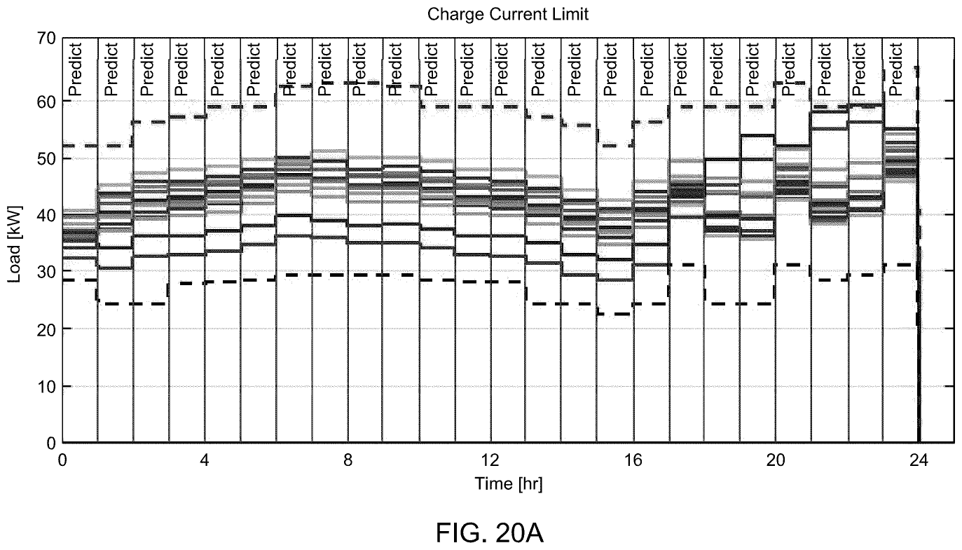

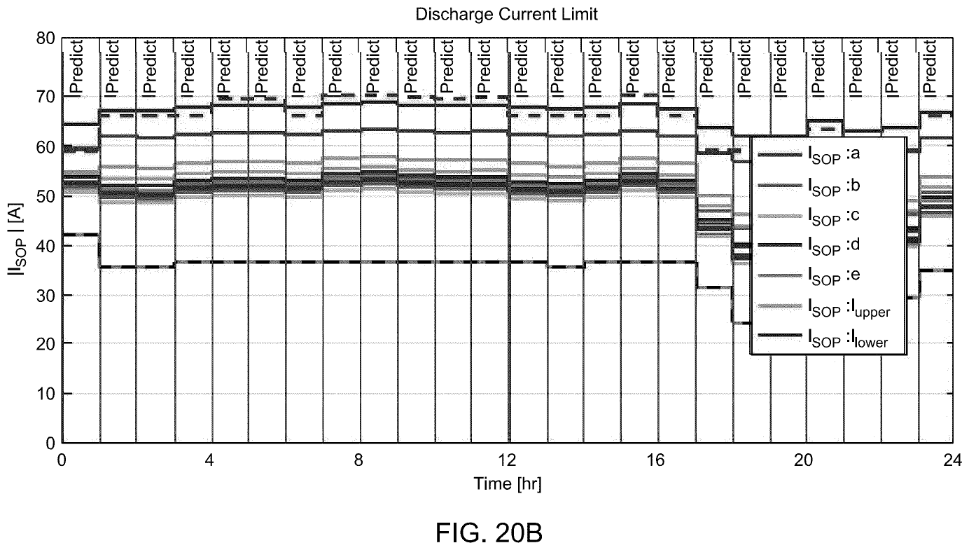

FIGS. 19A-19C show the evolution of voltage SOC and temperature of the cells. As expected the SOC and corresponding voltage of the cells increase whenever the Powerwall goes through charging current, and decreases when discharging. FIGS. 20A-20B show the corresponding charging and discharging SOP current values obtained for the Powerwall over a 24 hour load period. The solid lines show the SOP prediction for individual modules while the dashed lines show the safety current bound for the entire Powerwall. The SOP current is defined by the lower dashed as that is the maximum current that the entire pack can sustain safely. The prediction of the lower bound is accurate in this case as well, even with a large prediction horizon of 1 hour. This demonstrates the robustness and accuracy of the method according to the invention across different cell parameters, numbers of cells and prediction horizon.

As with the first embodiment, the second embodiment determines intervals and is thus scalable to any size battery system.

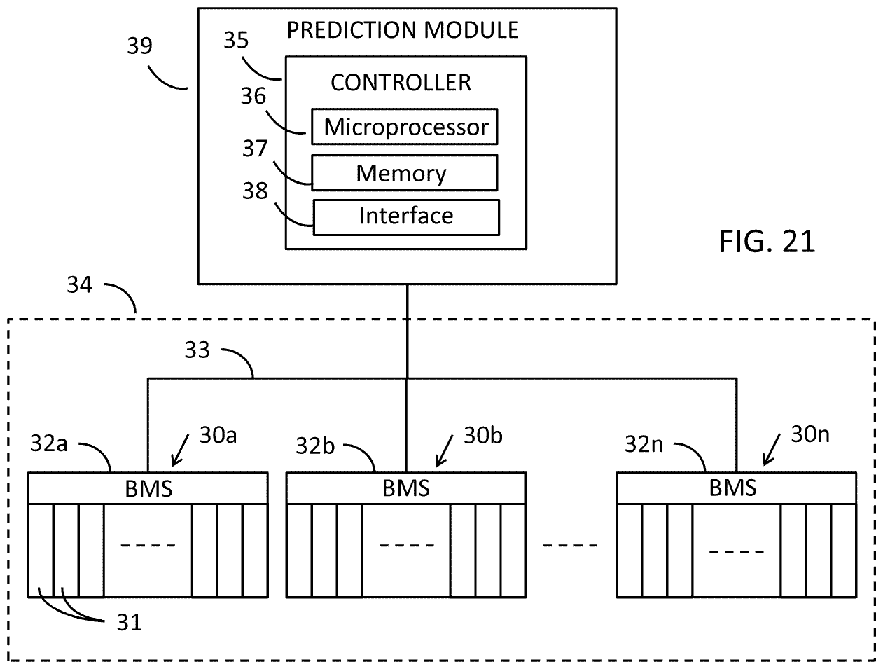

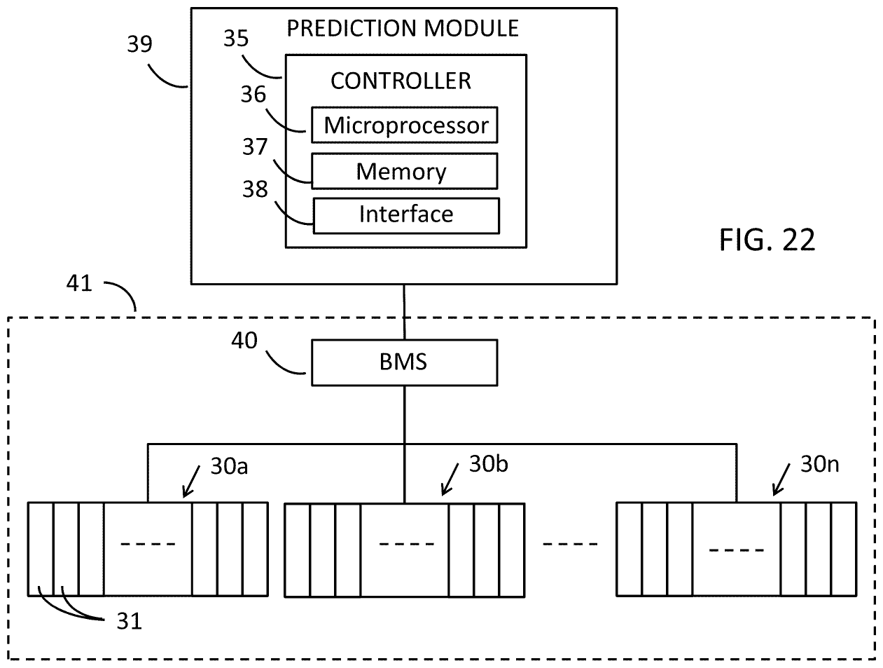

FIG. 21 is a schematic diagram of the system according to the invention. The storage system 34 (e.g., EV storage, grid storage) has a plurality of batteries 30a, 30b, . . . 30n connected in different arrangements (serial connection is shown here as an example). The system can have one battery or a number of batteries. Each battery has a respective battery management system (BMS) 32a-32n. Prediction module 39 carries out the prediction processing described above (FIGS. 7 and 11) and contains controller 35 which controls microprocessor 36, memory 37 and interface 38. Controller 35 also obtains the voltage, current and temperature measurements from the BMS for the interval observer process, as described above, over bus 33. While not shown, interfaces are present in the BMS to transfer data from the batteries to the prediction module 39.

Microprocessor 36 executes stored programs to carry out operations including the internal observer, interval state prediction, MGR, adaptive parameter bounding and reachability analysis operations. Controller 35 may read the stored programs from memory 40. The microprocessor may denote any circuit such as a CPU (Central Processing Unit), a GPU (Graphics Processing Unit), an Application Specific Integrated Circuit (ASIC), or a Programmable Logic Device (e.g., a Simple Programmable Logic Device (SPLD), a Complex Programmable Logic Device (CPLD), and a Field Programmable Gate Array (FPGA).

Memory 37 stores the programs for these operations as well as one or more programs for the operations of the controller such as data transfer with the BMS and execution of instructions received through interface 38. Memory 37 may be, for example, a Random Access Memory (RAM), a semiconductor memory element such as a flash memory, a hard disk drive, a solid state drive, and an optical disk. Memory 37 may also include a drive device that reads and writes various information from and into a portable storage medium such as a CD-ROM drive, DVD drive, and flash memory. The memory can be a solid state memory such as NAND for nonvolatile storage of the programs.

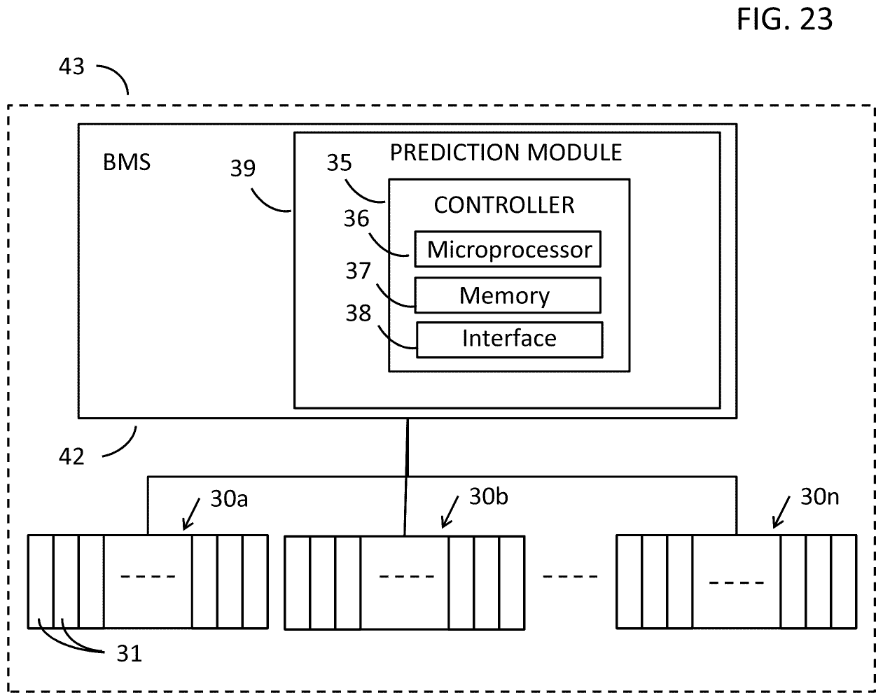

FIG. 23 is a third embodiment of the system according to the invention where there is one BMS 40 in system 41 for the cells 30a-30n and connected to prediction module 39. Yet another embodiment is shown in FIG. 24 where prediction module 39 is included in the BMS and prediction information is transmitted via interface 38 to a controller of system 43 (not shown).

1. A method of predicting state of power (SOP) for a battery, comprising:
estimating first state parameter bounds of the battery using an internal observer process;
obtaining a current value based upon the first state parameter bounds, system constraint variables, a scaling factor and a reference current using a modified reference governor process;
performing adaptive parameter bounding to obtain second state parameter bounds using the current value;
determining a constraint variable based upon the second state parameter bounds and whether the constraint variable is within the system constraint variables the using an interval prediction process;
generating a modified scaling factor based upon whether the constraint variable is within the system constraint variables;
using the modified scaling factor, repeating the obtaining, performing, determining and modifying to generate a final current value; and
estimating SOP based upon the final current value.

2. The method according to claim 1, wherein estimating the first state parameter bounds comprises estimating upper and lower bounds on intervals of state parameters for each of plural cells of the battery.

3. The method according to claim 1, wherein performing adaptive parameter bounding comprises determining minimum and maximum values of state of charge and temperature for charging and discharging of the battery.

4. The method according to claim 1, wherein estimating SOP comprises determine upper and lower SOP bounds.

5. The method according to claim 1, wherein generating the constraint variable comprises using reachability analysis to determine battery state parameter boundaries.

6. A method of predicting State of Power (SOP) for a battery, comprising:
obtaining battery state parameter boundaries using reachability analysis to obtain upper and lower boundaries of battery state parameters;
determining a current value based upon the battery state parameter boundaries using a modified reference governor process; and
repeating the obtaining and determining steps to generate a final current value; and
estimating SOP based upon the final current value.

7. The method according to claim 6, wherein obtaining the battery state parameter boundaries using reachability analysis comprises:
determining boundaries for SOC, voltage and temperature of a plurality of cells of the battery for both charging and discharging of the battery.

8. The method according to claim 6, wherein obtaining the battery state parameter boundaries using reachability analysis comprises determining boundaries of Jacobean matrices.

9. The method according to claim 6, wherein obtaining the battery state parameter boundaries using reachability analysis comprises determining boundaries of sign stable Jacobean matrices for both charging and discharging of the battery.

10. The method according to claim 6, wherein determining a current value based upon the battery state parameter boundaries using a modified reference governor process comprises using adaptive parameter bounding analysis.

11. A system for predicting State of Power (SOP) for a battery, comprising:
processing circuitry configured to:
estimate first state parameter bounds of the battery using an internal observer process;
obtain a current value based upon the first state parameter bounds, system constraint variables, a scaling factor and a reference current using a modified reference governor process;
perform adaptive parameter bounding to obtain second state parameter bounds using the current value;
determine a constraint variable based upon the second state parameter bounds and whether the constraint variable is within the system constraint variables the using an interval prediction process;
generate a modified scaling factor based upon whether the constraint variable is within the system constraint variables;
using the modified scaling factor, repeat the obtaining, performing, determining and modifying to generate a final current value; and
estimate SOP based upon the final current value.

12. The system according to claim 11, wherein the processing circuitry is configured to estimate the first state parameter bounds by estimating upper and lower bounds on intervals of state parameters for each of plural cells of the battery.

13. The system according to claim 11, wherein the processing circuitry is configured to performing adaptive parameter bounding by determining minimum and maximum values of state of charge and temperature for charging and discharging of the battery.

14. The system according to claim 11, wherein the processing circuitry is configured to estimating SOP by determining upper and lower SOP bounds.

15. The system according to claim 11, wherein the processing circuitry is configured to generate the constraint variable using reachability analysis to determine battery state parameter boundaries.

16. The system according to claim 11, wherein the processing circuitry is connected to a battery management system of a battery system containing the battery.
